(19) United States
(12) Patent Application Publication
(10) Pub. No.: US 2024/0180028 A1
(43) Pub. Date: May 30, 2024

(54) ORGANIC LIGHT EMITTING DIODE AND ORGANIC LIGHT EMITTING DEVICE INCLUDING THEREOF

(71) Applicant: LG Display Co., Ltd, Seoul (KR)

(72) Inventors: Gi-Hwan LIM, Paju-si (KR); Jong-Uk KIM, Paju-si (KR); In-Ae SHIN, Paju-si (KR); Jun-Yun KIM, Paju-si (KR)

(21) Appl. No.: 18/481,835

(22) Filed: Oct. 5, 2023

(30) Foreign Application Priority Data
Nov. 14, 2022 (KR) 10-2022-0151501

(51) Int. Cl. H10K 85/60

(52) U.S. Cl. CPC H10K 85/654; H10K 85/657; H10K 85/6572; H10K 85/658; H10K 50/12

(57) ABSTRACT

An organic light emitting diode includes at least one emitting material layer disposed between two electrodes includes a first compound having an azine moiety substituted two cyano groups and a carbazole moiety linked to the azine moiety through a phenylene group, and a second compound of a boron-based fluorescent material and an organic light emitting device including the organic light emitting diode. The excitons generated at the first compound are transferred efficiently to the second compound so that the luminous properties of the organic light emitting diode and/or the organic light emitting device can be improved.

### CROSS-REFERENCE TO RELATED APPLICATIONS

This application claims the benefit of and the priority of Republic of Korea Patent Application No. 10-2022-0151501, filed in the Republic of Korea on Nov. 14, 2022, which is expressly incorporated hereby in its entirety into the present application.

### BACKGROUND

### Technical Field

The present disclosure relates to an organic light emitting diode, and more particularly to, an organic light emitting diode with beneficial luminous properties and an organic light emitting device including the organic light emitting diode.

### Description of the Related Art

A flat display device including an organic light emitting diode (OLED) has attracted attention as a display device that can replace a liquid crystal display device (LCD). The OLED can be formed of a thin organic thin film equal to or less than 2000 Å, and the electrode configurations in the OLED can implement unidirectional or bidirectional images. Also, the OLED can be formed even on a flexible transparent substrate such as a plastic substrate so that a flexible or a foldable display device can be realized with ease using the OLED. In addition, the OLED can be driven at a lower voltage and the OLED has advantageous high color purity compared to the LCD.

In the OLED, holes injected from an anode and electrons injected from a cathode are recombined in an emitting material layer to form excitons with unstable energy state, and then the excitons are dropped to a ground sate with emitting light. Since fluorescent material uses only singlet excitons in the luminous process, the related art fluorescent material shows low luminous efficiency. On the contrary, phosphorescent material can show high luminous efficiency since it uses triplet exciton as well as singlet excitons in the luminous process. However, examples of phosphorescent material include metal complexes, which have a short luminous lifespan for commercial use.

### SUMMARY

Accordingly, embodiments of the present disclosure are directed to an organic light emitting diode and an organic light emitting device that substantially obviate one or more of the problems due to the limitations and disadvantages of the related art.

An aspect of the present disclosure is to provide an organic light emitting diode of which luminous efficiency and color purity can be improved and an organic light emitting device including the organic light emitting diode.

Additional features and aspects will be set forth in the description that follows, and in part will be apparent from the description, or may be learned by practice of the disclosed concepts provided herein. Other features and aspects of the disclosed concept may be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides an organic light emitting diode includes a first electrode; a second electrode facing the first electrode; and an emissive layer disposed between the first electrode and second electrode, and including at least one emitting material layer, wherein the at least one emitting material layer includes a first compound and a second compound, wherein the first compound includes an organic compound having the following structure of Chemical Formula 1, and wherein the second compound includes an organic compound having the following structure of Chemical Formula 7 or Chemical Formula 9:

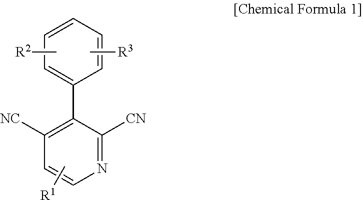

wherein, in the Chemical Formula 1,
R¹ is a hydrogen atom, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group; and
each of R₂ and R₃ is independently a moiety having the following structure of Chemical Formula 2,

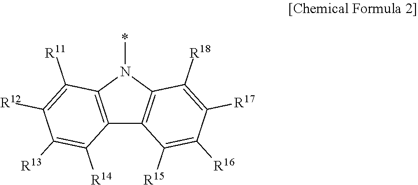

wherein, in the Chemical Formula 2,
each of R¹¹ to R¹⁸ is independently a hydrogen atom, a halogen atom, an unsubstituted or substituted C₁-C₂₀ alkyl group, an unsubstituted or substituted C₁-C₂₀ alkyl silyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C30 aryl amino group or an unsubstituted or substituted C₃-C₃₀ hetero aryl amino group, or
two adjacent groups among R¹¹ to R¹⁸ are linked together to form an unsubstituted or substituted C₆-C₂₀ aryl ring or an unsubstituted or substituted C₃-C₂₀ hetero aryl ring, where at least two adjacent groups among R¹¹ to R¹⁸ are linked together to form the following hetero aromatic ring having the structure of Chemical Formula 3,

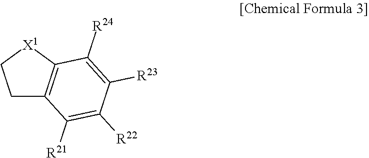

wherein, in the Chemical Formula 3,
X¹ is NR²⁵, O or S;
each of R²¹ to R²⁵ is independently a hydrogen atom, a halogen atom, an unsubstituted or substituted C₁-C₂₀ alkyl group, an unsubstituted or substituted C₁-C₂₀ alkyl silyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C30 aryl amino group or an unsubstituted or substituted C₃-C₃₀ hetero aryl amino group; and
a dotted line indicates a fused portion,

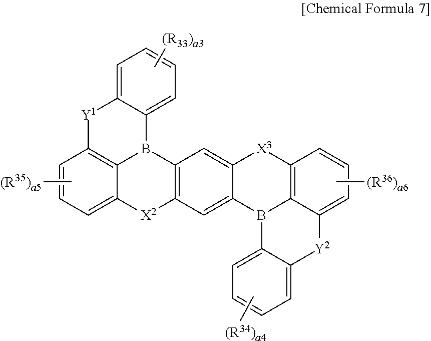

wherein, in the Chemical Formula 7,
Y¹ is O or NR³¹;
Y² is O or NR³²;
X² is O or NR³⁷;
X³ is O or NR³⁸;
each of R³¹ to R³⁸ is independently a hydrogen atom, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C3-C3o hetero aryl amino group, where each R³³ is identical to or different from each other when a3 is 2, 3 or 4, each R³⁴ is identical to or different from each other when a4 is 2, 3 or 4, each R³⁵ is identical to or different from each other when a5 is 2 or 3, and each R³⁶ is identical to or different from each other when a6 is 2 or 3, or
optionally,
R³¹ and R 33 , R³¹ and R 35 , R³⁵ and R 37 , R³⁷ and R 34 , R³⁴ and R 32 , R 32 and R 36 , R³⁶ and R³⁸ and/or
R³⁸ and R³³ are linked together to form an unsubstituted or substituted hetero aromatic ring including a nitrogen atom or an oxygen atom;
each of a3 and a4 is independently 0, 1, 2, 3 or 4; and
each of a5 and a6 is independently 0, 1, 2 or 3,

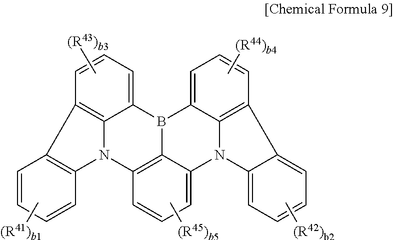

wherein, in the Chemical Formula 9,
each of R⁴¹ to R⁴⁴ is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group, where each R⁴¹ is identical to or different from each other when b1 is 2, 3 or 4, each R⁴² is identical to or different from each other when b2 is 2, 3 or 4, each R⁴³ is identical to or different from each other when b3 is 2 or 3, and each R⁴⁴ is identical to or different from each other when b4 is 2 or 3, or
optionally,
two adjacent R⁴¹ when bl is 2, 3 or 4, two adjacent R⁴² when b2 is 2, 3 or 4, two adjacent R⁴³ when b3 is 2 or 3 and/or two adjacent R⁴⁴ when b4 is 2 or 3 are linked together to form an unsubstituted or substituted C₆-C₂₀ aromatic ring or an unsubstituted or substituted C₃-C₂₀ hetero aromatic ring;
R⁴⁵ is an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group, where each R⁴⁵ is identical to or different from each other when b5 is 2 or 3, or
optionally,
two adjacent R⁴⁵ when b5 is 2 or 3 are linked together to form an unsubstituted or substituted C₆-C₂₀ aromatic ring or an unsubstituted or substituted C₃-C₂₀ hetero aromatic ring;
each of bl and b2 is independently 0, 1, 2, 3 or 4; and each of b3, b4 and b5 is independently 0, 1, 2 or 3.

The first compound can include an organic an organic compound having the following structure of Chemical Formula 4:

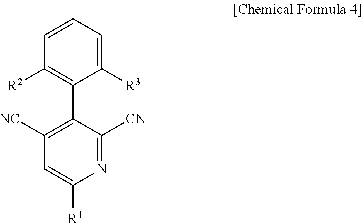

wherein, in the Chemical Formula 4,
each of R¹, R² and R³ is identical as defined in Chemical Formula 1.

The moiety having the structure of Chemical Formula 2 can be any one of the following moieties:

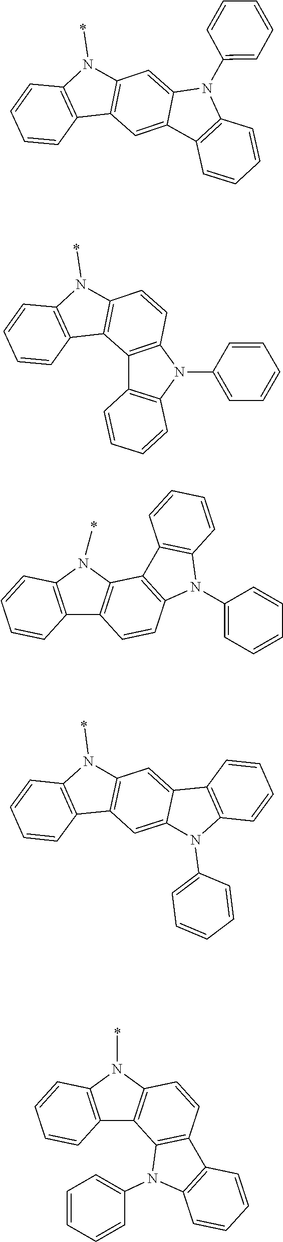

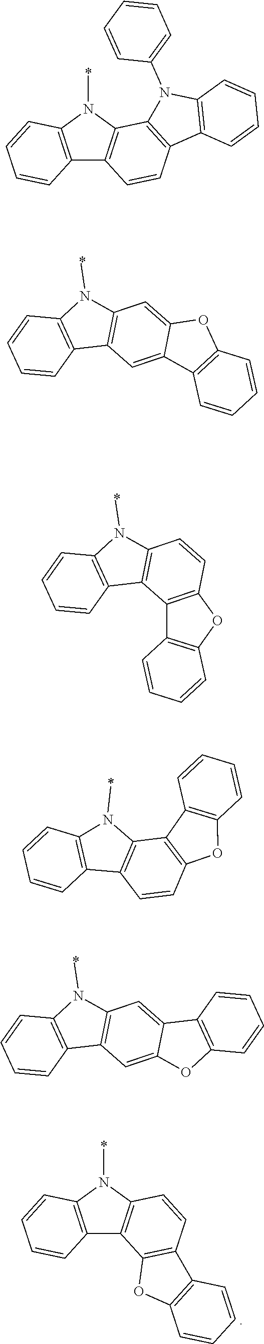 [SMILES: Cn1c2ccccc2c2ccc3c4ccccc4n(-c4ccccc4)c3c21 ; Cn1c2ccccc2c2cc3c(cc21)oc1ccccc13 ; Cn1c2ccccc2c2c3c(ccc21)oc1ccccc13 ; Cn1c2ccccc2c2ccc3oc4ccccc4c3c21 ; Cn1c2ccccc2c2cc3oc4ccccc4c3cc21 ; Cn1c2ccccc2c2c3oc4ccccc4c3ccc21]

In one example embodiment, the at least one emitting material layer can be a single-layered emitting material layer.

The single-layered emitting material layer can further include a third compound.

As an example, the third compound can include an organic compound having the following structure of Chemical Formula 11:

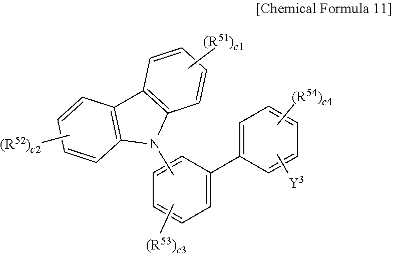

wherein, in the Chemical Formula 11,
each of R⁵¹ and R⁵² is independently an unsubstituted or substituted C₁-C₂₀ alkyl group, an unsubstituted or substituted C₆-C₃₀ aryl group or an unsubstituted or substituted C₃-C₃₀ hetero aryl group, where each R⁵¹ is identical to or different from each other when c1 is 2, 3 or 4, and where each R⁵² is identical to or different from each other when c2 is 2, 3 or 4;
each of R⁵³ and R⁵⁴ is independently an unsubstituted or substituted C₁-C₂₀ alkyl group, an unsubstituted or substituted C₆-C₃₀ aryl group or an unsubstituted or substituted C₃-C₃₀ hetero aryl group, or
optionally, R⁵³ and R⁵⁴ are linked together to form an unsubstituted or substituted hetero ring, where each R⁵³ is identical to or different from each other when c3 is 2, 3 or 4, and where each R⁵⁴ is identical to or different from each other when c4 is 2, 3 or 4;
Y³ has the following structure of Chemical Formula 12 or Chemical Formula 13;
each of c1 , c2, c3 and c4 is independently 0, 1, 2, 3 or 4,

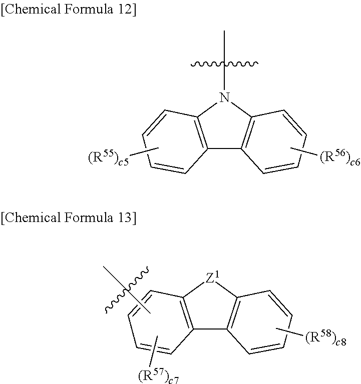

wherein, in the Chemical Formulae 12 and 13,
each of R⁵⁵, R⁵⁶, R⁵⁷ and R⁵⁸ is independently an unsubstituted or substituted C₁-C₂₀ alkyl group, an unsubstituted or substituted C₆-C₃₀ aryl group or an unsubstituted or substituted C₃-C₃₀ hetero aryl group, where each R⁵⁵ is identical to or different from each other when c5 is 2, 3 or 4, each R⁵⁶ is identical to or different from each other when c6 is 2, 3 or 4, each R⁵⁷ is identical to or different from each other when c7 is 2 or 3, and each R⁵⁸ is identical to or different from each other when c8 is 2, 3 or 4;
each of c5, c6 and c8 is independently 0, 1, 2, 3 or 4;
c7 is 0, 1, 2 or 3; and
Z¹ is NR⁵⁹, O or S, where R⁵⁹ is a hydrogen atom an unsubstituted or substituted C₁-C₂₀ alkyl group, an unsubstituted or substituted C₆-C₃₀ aryl group or an unsubstituted or substituted C₃-C₃₀ hetero aryl group.

In another example embodiment, the at least one emitting material layer can include a first emitting material layer; and a second emitting material layer disposed between the first electrode and the first emitting material layer or the first emitting material layer and the second electrode, and wherein the first emitting material layer can include the first compound and the second emitting material layer includes the second compound.

For example, the first emitting material layer can further include a third compound and the second emitting material layer can further include a fourth compound.

Each of the third compound and the fourth compound independently can include the organic compound having the structure of Chemical Formula 11.

In another example embodiment, the at least one emitting material layer can further include a third emitting material layer disposed oppositely to the second emitting material layer with respect to the first emitting material layer.

The third emitting material layer can include a fifth compound and a sixth compound.

The fifth compound can include the organic compound having the structure of Chemical Formula 7 or Chemical Formula 9.

The sixth compound can include the organic compound having the structure of Chemical Formula 11.

In another example embodiment, the emissive layer can include a first emitting part disposed between the first electrode and the second electrode; a second emitting part disposed between the first emitting part and the second electrode; and a first charge generation layer disposed between the first emitting part and the second emitting part, and wherein at least one of the first emitting part and the second emitting part can include the at least one emitting material layer.

As an example, the second emitting part can include the at least one emitting material layer and the first emitting part can include a blue emitting material layer.

The second emitting part can include a first layer disposed between the first charge generation layer and the second electrode; and a second layer disposed between the first layer and the second electrode, and wherein the one of the first layer and the second layer can include the at least one emitting material layer.

For example, the second layer can include the at least one emitting material layer and the first layer can include a red emitting material layer.

Optionally, the second emitting part can further include a third layer disposed between the first layer and the second layer, and wherein the third layer can include a yellow-green emitting material layer.

In another example embodiment, the emissive layer can further include a third emitting part disposed between the second emitting part and the second electrode; and a second charge generation layer disposed between the second emitting part and the third emitting part, and wherein at least one of the first emitting part, the second emitting part and the third emitting part can include the at least one emitting material layer.

In yet another aspect, the present disclosure provides an organic light emitting device, for example, an organic light emitting display device or an organic light emitting illumination device, includes a substrate and the organic light emitting diode over the substrate.

Triplex excitons can be converted upwardly to singlet excitons by RISC in the first compound having delayed fluorescent property. The singlet exciton generated at the first compound having delayed fluorescent property can be transferred efficiently to the second compound. Internal quantum efficiency of 100% is realized in the first compound with beneficial luminous efficiency and the excitons generated at the first compound can be transferred to the second compound with beneficial color purity.

The energy bandgap between LUMO energy level of the first compound and LUMO energy level of the third compound of host is narrower than the energy bandgap between HOMO energy level of the first compound and HOMO energy level of the third compound. Holes and electrons can be transferred to the first compound from the third compound in balance in the emitting material layer.

As the hole injection efficiency and the exciton generation efficiency become improved, the luminous efficiency of the organic light emitting diode can be improved. As the ultimate light emission is occurred at the second compound with narrow FWHM and excellent luminous lifespan, the color purity and the lifespan of the organic light emitting diode can be improved.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device in accordance with the present disclosure.

FIG. 2 illustrates a schematic cross-sectional view of an organic light emitting display device as an example of an organic light emitting device in accordance with an example embodiment of the present disclosure.

FIG. 3 illustrates a schematic cross-sectional view of an organic light emitting diode in accordance with an example embodiment of the present disclosure.

FIG. 4 illustrates a schematic cross-sectional view of an organic light emitting diode in accordance with another example embodiment of the present disclosure.

FIG. 5 illustrates a schematic cross-sectional view of an organic light emitting diode in accordance with another example embodiment of the present disclosure.

FIG. 6 illustrates a schematic cross-sectional view of an organic light emitting diode in accordance with another example embodiment of the present disclosure.

FIG. 7 illustrates a schematic cross-sectional view of an organic light emitting display device as an example of an organic light emitting device in accordance with another example embodiment of the present disclosure.

FIG. 8 illustrates a schematic cross-sectional view of an organic light emitting diode in accordance with another example embodiment of the present disclosure.

### DETAILED DESCRIPTION

Reference will now be made in detail to aspects of the disclosure, examples of which are illustrated in the accompanying drawings. Wherever possible, the same reference numbers will be used throughout the drawings to refer to the same or like parts.

The present disclosure relates to an organic light emitting diode where an emitting material layer or adjacently disposed different emitting material layer include a first compound and a second compound that can transfer exciton energy, and optionally a third compound, and an organic light emitting device including the organic light emitting diode. The organic light emitting diode can be applied to an organic light emitting device such as an organic light emitting display device or an organic light emitting illumination device. As an example, an organic light emitting display device will be described.

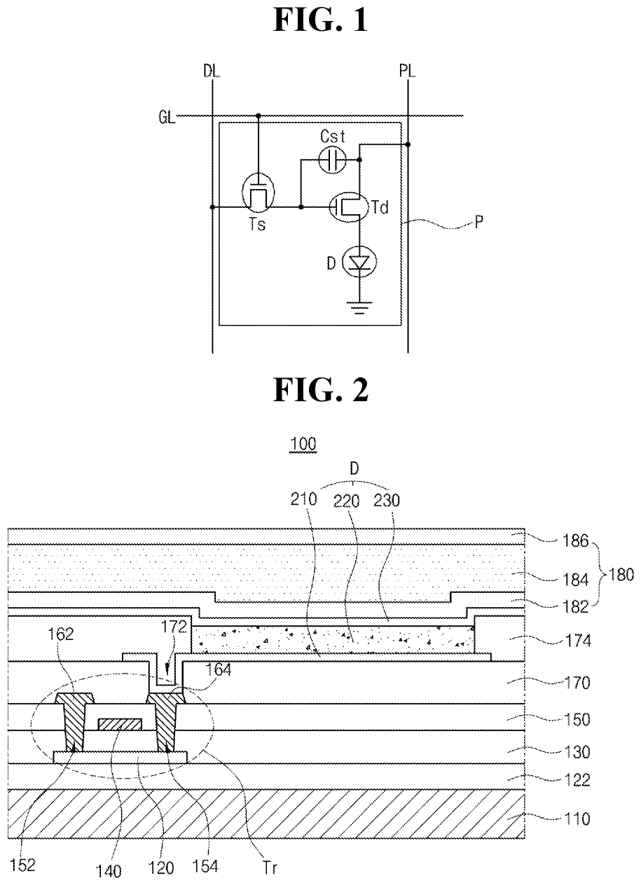

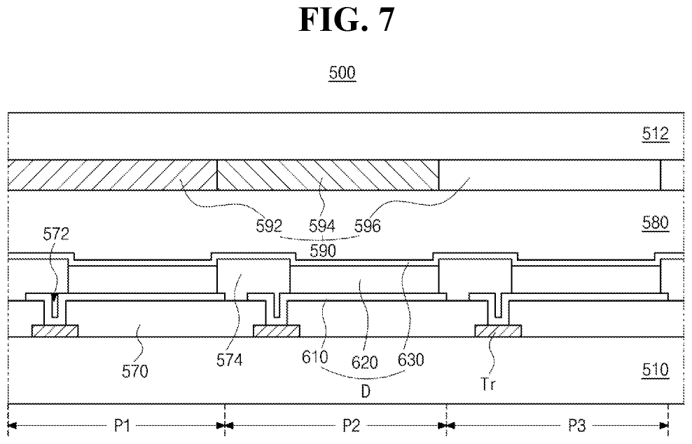

FIG. 1 illustrates a schematic circuit diagram of an organic light emitting display device in accordance with the present disclosure. As illustrated in FIG. 1, a gate line GL, a data line DL and power line PL, each of which crosses each other to define a pixel region P, in an organic light emitting display device 100. A switching thin film transistor Ts, a driving thin film transistor Td, a storage capacitor Cst and an organic light emitting diode D are disposed within the pixel region P. The pixel region P can include a first pixel region P1 (FIG. 7), a second pixel region P2 (FIG. 7) and a third pixel region P3 (FIG. 7). However, embodiments of the present disclosure are not limited to such examples.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

The driving thin film transistor Td is turned on by the data signal applied to the gate electrode 140 (FIG. 2) so that a current proportional to the data signal is supplied from the power line PL to the organic light emitting diode D through the driving thin film transistor Td. And then, the organic light emitting diode D emits light having a luminance proportional to the current flowing through the driving thin film transistor Td. In this case, the storage capacitor Cst is charged with a voltage proportional to the data signal so that the voltage of the gate electrode 140 in the driving thin film transistor Td is kept constant during one frame. Therefore, the organic light emitting display device can display a desired image.

FIG. 2 illustrates a schematic cross-sectional view of an organic light emitting display device in accordance with an example embodiment of the present disclosure. As illustrated in FIG. 2, the organic light emitting display device 100 includes a substrate 110, a thin film transistor Tr disposed on the substrate 110 and an organic light emitting diode (OLED) D connected to the thin film transistor Tr.

For example, the substrate 110 defines a first pixel region, a second pixel region and a third pixel region, and the OLED D is located at each pixel region. The OLED D emitting red color light, green color light and blue color light is disposed in each of the first to third pixel region, respectively.

The substrate 110 can include transparent material. In one example embodiment, the substrate 110 can include, but is not limited to, glass, thin flexible material and/or polymer plastics. For example, the flexible material can be selected from the group, but is not limited to, polyimide (PI), polyethersulfone (PES), polyethylenenaphthalate (PEN), polyethylene terephthalate (PET), polycarbonate (PC) and/or combinations thereof. The substrate 110 on which the thin film transistor Tr and the OLED D constitutes an array substrate.

A buffer layer 122 can be disposed on the substrate 110. The thin film transistor Tr can be disposed on the buffer layer 122. The buffer layer 122 can be omitted.

A semiconductor layer 120 is disposed on the buffer layer 122. In one example embodiment, the semiconductor layer 120 can include, but is not limited to, oxide semiconductor materials. In this case, a light-shield pattern may be disposed under the semiconductor layer 120, and the light-shield pattern can prevent light from being incident toward the semiconductor layer 120, and thereby, preventing or reducing the semiconductor layer 120 from being degraded by the light. Alternatively, the semiconductor layer 120 can include polycrystalline silicon. In this case, opposite edges of the semiconductor layer 120 can be doped with impurities.

A gate insulating layer 130 including insulating material is disposed on the semiconductor layer 120. The gate insulating layer 130 can include, but is not limited to, an inorganic insulating material such as silicon oxide (SiOₓ, wherein 0<x≤2) or silicon nitride (SiNₓ, wherein 0<x≤2).

A gate electrode 140 made of conductive material such as metal is disposed on the gate insulating layer 130 so as to correspond to a center of the semiconductor layer 120. While the gate insulating layer 130 is disposed on a whole area of the substrate 110 as shown in FIG. 2, the gate insulating layer 130 can be patterned identically as the gate electrode 140.

An interlayer insulating layer 150 including insulating material is disposed on the gate electrode 140 and covers an entire surface of the substrate 110. The interlayer insulating layer 150 can include, but is not limited to, an inorganic insulating material such as silicon oxide (SiOₓ) (SiOₓ, wherein 0<x≤2) or silicon nitride (SiNₓ) (SiNₓ, wherein 0<x≤2), or an organic insulating material such as benzocyclobutene or photo-acryl.

The interlayer insulating layer 150 has first and second semiconductor layer contact holes 152 and 154 that expose or do not cover a portion of the surface nearer to the opposing ends than to a center of the semiconductor layer 120. The first and second semiconductor layer contact holes 152 and 154 are disposed on opposite sides of the gate electrode 140 and spaced apart from the gate electrode 140. The first and second semiconductor layer contact holes 152 and 154 are formed within the gate insulating layer 130 in FIG. 2. Alternatively, the first and second semiconductor layer contact holes 152 and 154 can be formed only within the interlayer insulating layer 150 when the gate insulating layer 130 is patterned identically as the gate electrode 140.

A source electrode 162 and a drain electrode 164, which are made of conductive material such as metal, are disposed on the interlayer insulating layer 150. The source electrode 162 and the drain electrode 164 are spaced apart from each other on opposing sides of the gate electrode 140, and contact both sides of the semiconductor layer 120 through the first and second semiconductor layer contact holes 152 and 154, respectively.

The semiconductor layer 120, the gate electrode 140, the source electrode 162 and the drain electrode 164 constitute the thin film transistor Tr, which acts as a driving element. The thin film transistor Tr in FIG. 2 has a coplanar structure in which the gate electrode 140, the source electrode 162 and the drain electrode 164 are disposed on the semiconductor layer 120. Alternatively, the thin film transistor Tr can have an inverted staggered structure in which a gate electrode is disposed under a semiconductor layer and a source and drain electrodes are disposed on the semiconductor layer. In this case, the semiconductor layer can include amorphous silicon.

The organic light emitting diode D is electrically connected to the thin film transistor Tr in each of the first to third pixel regions SP1, SP2 and SP3, respectively. The gate line GL and the data line DL, which cross each other to define a pixel region P, and a switching element Ts, which is connected to the gate line GL and the data line DL, can be further formed in each of the pixel regions SP1, SP2 and SP3. The switching element Ts is connected to the thin film transistor Tr, which is a driving element. In addition, the power line PL is spaced apart in parallel from the gate line GL or the data line DL. The thin film transistor Tr can further include a storage capacitor Cst configured to constantly keep a voltage of the gate electrode 140 for one frame.

A passivation layer 170 is disposed on the source and drain electrodes 162 and 164. The passivation layer 170 covers the thin film transistor Tr on the whole substrate 110. The passivation layer 170 has a flat top surface and a drain contact hole 172 that exposes or does not cover the drain electrode 164 of the thin film transistor Tr. While the drain contact hole 172 is disposed on the second semiconductor layer contact hole 154, it may be spaced apart from the second semiconductor layer contact hole 154.

The OLED D includes a first electrode 210 that is disposed on the passivation layer 170 and connected to the drain electrode 164 of the thin film transistor Tr. The OLED D further includes an emissive layer 220 and a second electrode 230 each of which is disposed sequentially on the first electrode 210.

The first electrode 210 is formed separately for each pixel region. The first electrode 210 can be an anode and include conductive material with relatively high work function value, for example, a transparent conductive oxide (TCO). For example, the first electrode 210 can include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or the like.

When the organic light emitting display device 100 is a bottom-emission type, the first electrode 210 can have a single-layered structure of transparent conductive oxide. Alternatively, when the organic light emitting display device 100 is a top-emission type, a reflective electrode or a reflective layer may be disposed under the first electrode 210. For example, the reflective electrode or the reflective layer can include, but is not limited to, silver (Ag) or aluminum-palladium-copper (APC) alloy. For example, the first electrode 210 can have a triple-layered structure of ITO/Ag/ITO or ITO/APC/ITO.

In addition, a bank layer 174 is disposed on the passivation layer 170 in order to cover edges of the first electrode 210. The bank layer 174 exposes or does not cover a center of the first electrode 210. The bank layer 174 can be omitted.

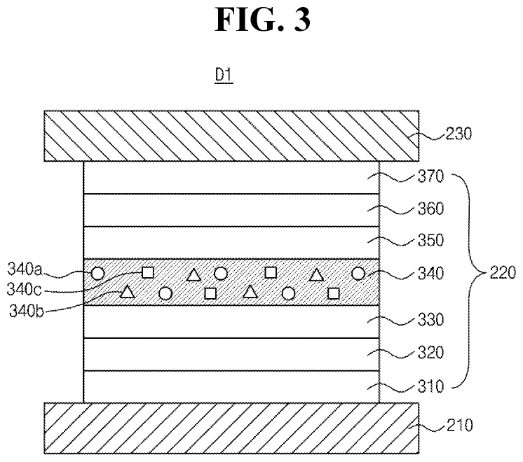

An emissive layer 220 is disposed on the first electrode 210. In one example embodiment, the emissive layer 220 can have a single-layered structure of an emitting material layer (EML). Alternatively, the emissive layer 220 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIGS. 3 to 6). For example, the emissive layer can be applied to an organic light emitting diode having a single emitting part and located in each of the first pixel region, second pixel region and the third pixel region, respectively. Alternatively, the emissive layer can be applied to an organic light emitting diode of a tandem structure where multiple emitting parts are stacked.

As described below, the emissive layer 220 can include a first compound having delayed fluorescent property, a second compound having fluorescent property, and optionally, a third compound of host. In this case, the luminous efficiency, luminous lifespan and/or color purity of the OLED D and the organic light emitting display device 100 can be improved significantly.

The second electrode 230 is disposed on the substrate 110 above which the emissive layer 220 is disposed. The second electrode 230 can be disposed on a whole display area. The second electrode 230 can include a conductive material with a relatively low work function value compared to the first electrode 210. The second electrode 230 can be a cathode providing electrons. In one example embodiment, the second electrode 230 can include a highly reflective material, for example, at least one of, but is not limited to, aluminum (Al), magnesium (Mg), calcium (Ca), silver (Ag), alloy thereof and/or combinations thereof such as aluminum-magnesium alloy (Al-Mg). When the organic light emitting display device 100 is a top-emission type, the second electrode 230 is thin so as to have light-transmissive (semi-transmissive) property.

An encapsulation film 180 can be disposed on the second electrode 230 in order to prevent or reduce outer moisture from penetrating into the OLED D. For example, the encapsulation film 180 can have, but is not limited to, a laminated structure of a first inorganic insulating layer 182, an organic insulating layer 184 and a second inorganic insulating layer 186. The encapsulation film 180 can be omitted.

The organic light emitting display device 100 can further include a polarizing plate in order to reduce reflection of external light. For example, the polarizing plate can be a circular polarizing plate. When the organic light emitting display device 100 is the bottom-emission type, the polarizing plate can be disposed under the substrate 110. Alternatively, when the organic light emitting display device 100 is the top-emission type, the polarizing plate can be disposed on the encapsulation film 180. In addition, a cover window can be attached to the encapsulation film 180 or the polarizing plate in the organic light emitting display device 100 of the top-emission type. In this case, the substrate 110 and the cover window may have a flexible property, thus the organic light emitting display device 100 may be a flexible display device.

The OLED D is described in more detail. FIG. 3 illustrates a schematic cross-sectional view of an organic light emitting diode with a single emitting part in accordance with an example embodiment of the present disclosure. As illustrated in FIG. 3, the OLED D1 includes a first electrode 210, a second electrode 230 facing the first electrode 210 and an emissive layer 220 disposed between the first and second electrodes 210 and 230. The organic light emitting display device 100 (FIG. 2) includes a red pixel region, a green pixel region and a blue pixel region, and the OLED D1 can be located at the green pixel region.

The emissive layer 220 includes an emitting material layer (EML) 340. The emissive layer 220 can include at least one of a hole transport layer (HTL) 320 disposed between the first electrode 210 and the EML 340 and an electron transport layer (ETL) 360 disposed between the EML 340 and the second electrode 230. In addition, the emissive layer 220 can include at least one of a hole injection layer (HIL) 310 disposed between the first electrode 210 and the HTL 320 and an electron injection layer (EIL) 370 disposed between the second electrode 230 and the ETL 360. Alternatively, the emissive layer 220 can further include at least one of an electron blocking layer (EBL) 330 as a first exciton blocking layer disposed between the HTL 320 and the EML 340 and/or a hole blocking layer (HBL) 350 as a second exciton blocking layer disposed between the EML 340 and the ETL 360.

The first electrode 210 can be an anode proving holes to the EML 340. The first electrode 210 can include conductive material with relatively high work function value, for example, TCO. In one example embodiment, the first electrode 210 can include, but is not limited to, ITO, IZO, ITZO, SnO, ZnO, ICO, AZO and/or combinations thereof.

The second electrode 230 can be a cathode providing electrons to the EML 340. The second electrode 230 can include, but is not limited to, conductive material with relatively low work function value, for example highly reflective material such as Al, Mg, Ca, Ag, alloy thereof and/or combinations thereof.

The EML 340 includes a first compound 340a, a second compound 340b, and optionally, a third compound 340c. The first compound 340a can include delayed fluorescent material, the second compound 340b can include fluorescent material and the third compound 340c can include a host.

The first compound 340a with delayed fluorescent property can have a first moiety of an electron acceptor group consisting of an azine ring substituted with at least one cyano group, a second moiety of plural electron donor groups including a carbazole ring, and a phenylene linking group between the first moiety and the second moiety. The first compound 340a can have the following structure of Chemical Formula 1:

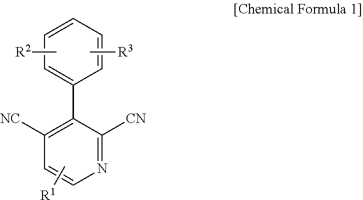

wherein, in the Chemical Formula 1,
R¹ is a hydrogen atom, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group; and each of R² and R³ is independently a moiety having the following structure of Chemical
Formula 2,

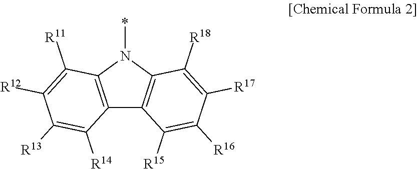

wherein, in the Chemical Formula 2,
each of R¹¹ to R¹⁸ is independently a hydrogen atom, a halogen atom, an unsubstituted or substituted C₁-C₂₀ alkyl group, an unsubstituted or substituted C₁-C₂₀ alkyl silyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group, or
two adjacent groups among R¹¹ to R¹⁸ are linked together to form an unsubstituted or substituted C₆-C₂₀ aryl ring or an unsubstituted or substituted C₃-C₂₀ hetero aryl ring, where at least two adjacent groups among R¹¹ to R¹⁸ are linked together to form the following hetero aromatic ring having the structure of Chemical Formula 3,

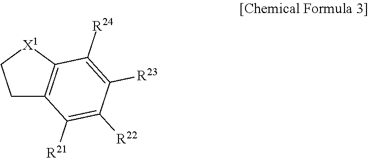

wherein, in the Chemical Formula 3,
X¹ is NR²⁵, O or S;
each of R²¹ to R²⁵ is independently a hydrogen atom, a halogen atom, an unsubstituted or substituted C₁-C₂₀ alkyl group, an unsubstituted or substituted C₁-C₂₀ alkyl silyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group; and
a dotted line indicates a fused portion.

As used herein, the term “unsubstituted” means that hydrogen is directly linked to a carbon atom. “Hydrogen”, as used herein, can refer to protium, deuterium and tritium.

As used herein, “substituted” means that the hydrogen is replaced with a substituent. The substituent can comprise, but is not limited to, an unsubstituted or halogen-substituted C₁-C₂₀ alkyl group, an unsubstituted or halogen-substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, an unsubstituted or halogen-substituted C₁-C₁₀ alkyl silyl group, an unsubstituted or halogen-substituted C₁-C₁₀ alkoxy silyl group, an unsubstituted or halogen-substituted C₃-C₂₀ cyclo alkyl silyl group, an unsubstituted or halogen-substituted C₆-C₃₀ aryl silyl group, an unsubstituted or halogen-substituted C₃-C₃₀ hetero aryl silyl group, an unsubstituted or alkyl-substituted C₆-C₃₀ aryl group, an unsubstituted or alkyl-substituted C₃-C₃₀ hetero aryl group.

In an example embodiment, the substituent on the C₆-C₃₀ aryl group, the C₃-C₃₀ hetero aryl group, the C₆-C₃₀ aryl amino group, the C₃-C₃₀ hetero aryl amino group, the C₆-C₂₀ aromatic ring and/or the C₃-C₂₀ hetero aryl ring can include at least one of a C₁-C₂₀ alkyl group, a C₆-C₃₀ aryl group, a C₃-C₃₀ hetero aryl group, a C₆-C₃₀ aryl amino group and a C₃-C₃₀ hetero aryl amino group.

As used herein, the term “hetero” in terms such as “a hetero aromatic group”, “a hetero cyclo alkylene group”, “a hetero arylene group”, “a hetero aryl alkylene group”, “a hetero aryl oxylene group”, “a hetero cyclo alkyl group”, “a hetero aryl group”, “a hetero aryl alkyl group”, “a hetero aryl oxy group”, “a hetero aryl amino group” and the likes means that at least one carbon atom, for example 1 to 5 carbons atoms, constituting an aliphatic chain, an alicyclic group or ring or an aromatic group or ring is substituted with at least one hetero atom selected from the group consisting of N, O, S and P.

As used herein, the C₆-C₃₀ aryl group can include, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl, unless otherwise indicated. The C₆-C₃₀ arylene group can be a bivalent substituent corresponding to the aryl group, unless otherwise indicated.

As used herein, the C₃-C₃₀ hetero aryl group can comprise, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked Spiro acridinyl, dihydroacridinyl substituted with at least one C₁-C₁₀ alkyl and N-substituted spiro fluorenyl, unless otherwise indicated. The C₃-C₃₀ hetero arylene group can be a bivalent substituent corresponding to the hetero aryl group, unless otherwise indicated.

As an example, the C₆-C₂₀ aromatic ring and the C₃-C₂₀ hetero aromatic ring that can be formed by two adjacent groups among R¹¹ to R¹⁸ in Chemical Formula 2 cannot be limited to specific rings. For example, the C₆-C₂₀ aromatic ring and the C₃-C₂₀ hetero aromatic ring that can be formed by two adjacent groups among R¹¹ to R¹⁸ in Chemical Formula 2 can include, but is not limited to, a benzene ring, a naphthalene ring, an anthracene ring, a phenanthrene ring, an indene ring, a fluorene ring, a pyridine ring, a pyrimidine ring, a triazine ring, a quinoline ring, an indole ring, a benzo-furan ring, a benzo-thiophene ring, a dibenzo-furan ring, a dibenzo-thiophene ring and combinations thereof.

For example, each of the C₆-C₃₀ aryl group, the C₃-C₃₀ hetero aryl group, the C₆-C₃₀ aryl amino group, the C₃-C₃₀ hetero aryl amino group, the C₆-C₂₀ aromatic group and the C₃-C₂₀ hetero aromatic ring of R¹ to R³ in Chemical Formula 1, R¹¹ to R¹⁸ in Chemical Formula 2 and R²¹ to R²⁵ in Chemical Formula 3 can be independently unsubstituted or substituted with at least one of a C₁-C₁₀ alkyl group (e.g., C₁-C₅ alkyl group such as tert-butyl), a C₆-C₃₀ aryl group (e.g., C₆-C₁₅ aryl group such as phenyl, napthyl), a C₃-C₃₀ hetero aryl group (e.g., C₃-C₁₅ hetero aryl group such as pyridyl) and a C₆-C₂₀ aryl amino group (e.g., biphenyl amino group), respectively.

In Chemical Formula 1, the pyridine moiety substituted with cyano groups acts as electron acceptor and the fused hetero aromatic ring having at least one nitrogen atom having the structure of Chemical Formula 2 acts as electron donor. The organic compound having the structure of Chemical Formula 1 has delayed fluorescent properties.

The electron donor moiety having the structure of Chemical Formula 2 includes a 5-mebered ring with a nitrogen atom between two benenene rings. Accordingly, as the bonding strength between the electron acceptor moiety and the elector donor moiety maximizes, the organic compound having the structure of Chemical Formula 2 has beneficial thermal stability. As the first compound 340a with delayed fluorescent properties has beneficial luminous property, it is possible to realize hyper-fluorescence as sufficient exciton energy transfers to the second compound 340b from the first compound 340a.

The electron donor moiety with fused multiple rings in the first compound 340a having the structure of Chemical Formula 1 has large volume so that steric hindrance can be include between the electron donor moiety and the electron acceptor moiety. In addition, the first compound 340a includes multiple electron donor moieties with large volume. Steric hindrance between multiple electron donor moieties can be included so that the first compound 340a can have enhanced delayed fluorescent property.

The first compound 340a has very narrow energy bandgap ΔE_{ST} between its excited singlet energy level S₁ and its excited triplet energy level T₁. Accordingly, triplet exciton can be converted rapidly to singlet exciton by Reverse Inter-System Crossing (RISC) in the first compound 340a as spin-orbital coupling (SOC) enhances.

The first compound 340a having the structure of Chemical Formulae 1 to 3 has delayed fluorescent properties. In addition, the first compound 340a has excited singlet energy level, excited triplet energy level, highest occupied molecular orbital (HOMO) energy level, lowest unoccupied molecular orbital (LUMO) energy level and appropriate luminous properties sufficiently to receive exciton energy from the third compound 340c and to transfer efficiently the exciton energy to the second compound 340b.

In one example embodiment, R¹ of substituent of the pyridine ring as the electron acceptor can be linked adjacently to a nitrogen atom of the pyridine ring and each of the carbaozle rings as the electron donor can be linked to an ortho- position of the benzene ring with respect to the pyridine ring. As an example, the first compound 340a can have, but is not limited to, the following structure of Chemical Formula 4:

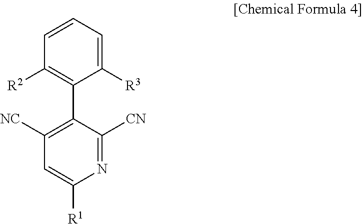

wherein, in the Chemical Formula 4,
each of R¹, R² and R³ is identical as defined in Chemical Formula 1.

At least two groups among R¹¹ to R¹⁸ in Chemical Formula 2 can be linked together to form the fused hetero aromatic ring having the structure of Chemical Formula 3, As an example, at least two groups among R¹¹ to R¹⁸ in Chemical Formula 2 can be linked together to form an indene ring, an indole ring, a benzo-furan ring and/or a benzo-thiophene ring each of which can be unsubstituted or substituted. In this case, the hetero aromatic moiety having the structure of Chemical Formula 2 acting as electron donor can include, but is not limited to, an indeno-carbazolyl moiety, an indolo-carbazolyl moiety, a benzofuro-carbazolyl moiety and/or a benzothieno-carbazoly moiety. For example, the electron donor moiety having the structure of Chemical 2 can include, but is not limited to, any one moiety selected from the following Chemical Formula 5:

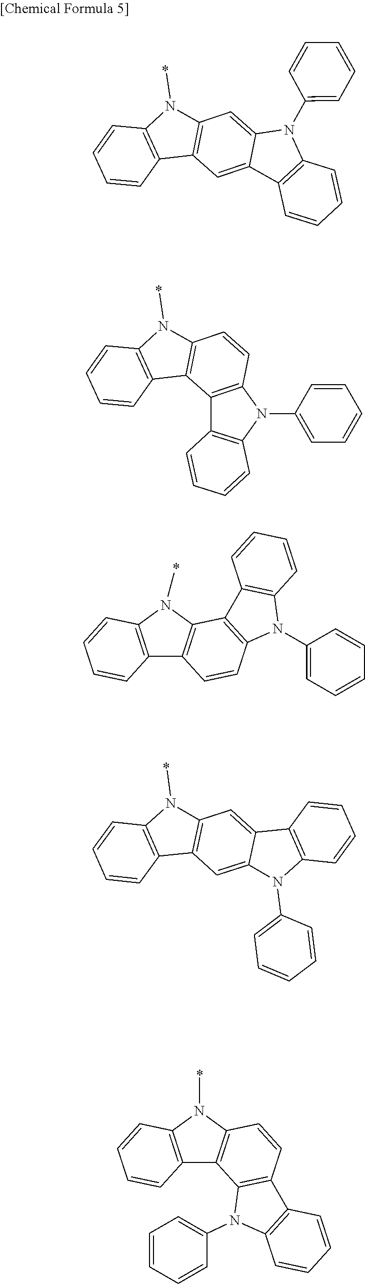

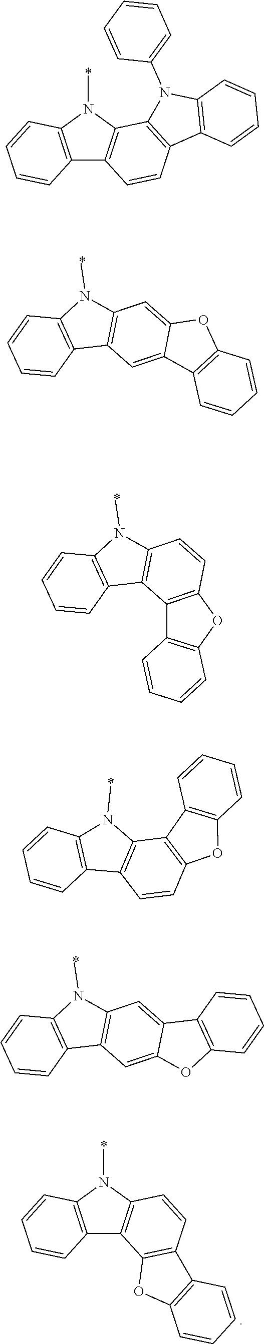 [SMILES: Cn1c2ccccc2c2ccc3c4ccccc4n(-c4ccccc4)c3c21 ; Cn1c2ccccc2c2cc3c(cc21)oc1ccccc13 ; Cn1c2ccccc2c2c3c(ccc21)oc1ccccc13 ; Cn1c2ccccc2c2ccc3oc4ccccc4c3c21 ; Cn1c2ccccc2c2cc3oc4ccccc4c3cc21 ; Cn1c2ccccc2c2c3oc4ccccc4c3ccc21]

More particularly, the first compound 340a can be, but is not limited to, at least one of the following organic compounds of Chemical Formula 6:

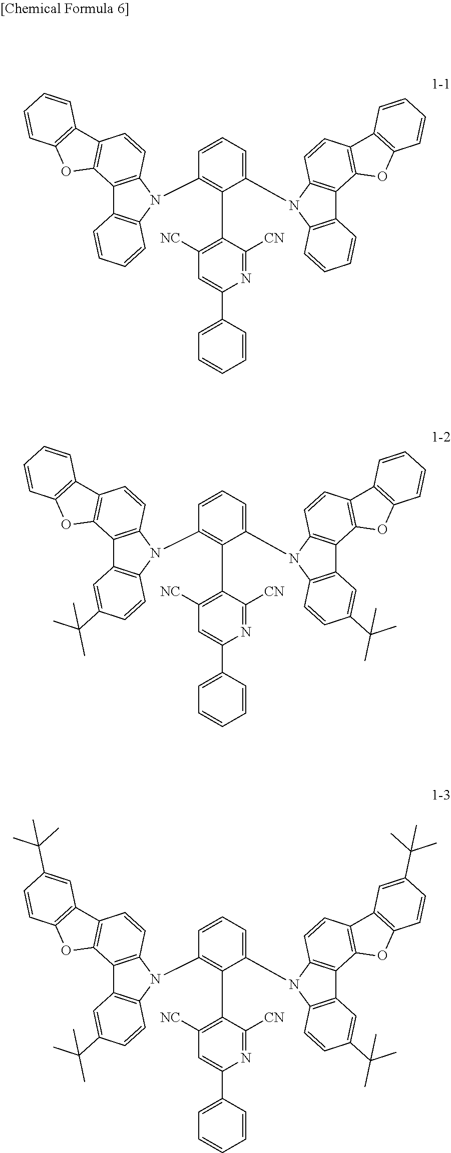 [SMILES: N#Cc1cc(-c2ccccc2)nc(C#N)c1-c1c(-n2c3ccccc3c3c4oc5ccccc5c4ccc32)cccc1-n1c2ccccc2c2c3oc4ccccc4c3ccc21 ; CC(C)(C)c1ccc2c(c1)c1c3oc4ccccc4c3ccc1n2-c1cccc(-n2c3ccc(C(C)(C)C)cc3c3c4oc5ccccc5c4ccc32)c1-c1c(C#N)cc(-c2ccccc2)nc1C#N ; CC(C)(C)c1ccc2oc3c(ccc4c3c3cc(C(C)(C)C)ccc3n4-c3cccc(-n4c5ccc(C(C)(C)C)cc5c5c6oc7ccc(C(C)(C)C)cc7c6ccc54)c3-c3c(C#N)cc(-c4ccccc4)nc3C#N)c2c1]

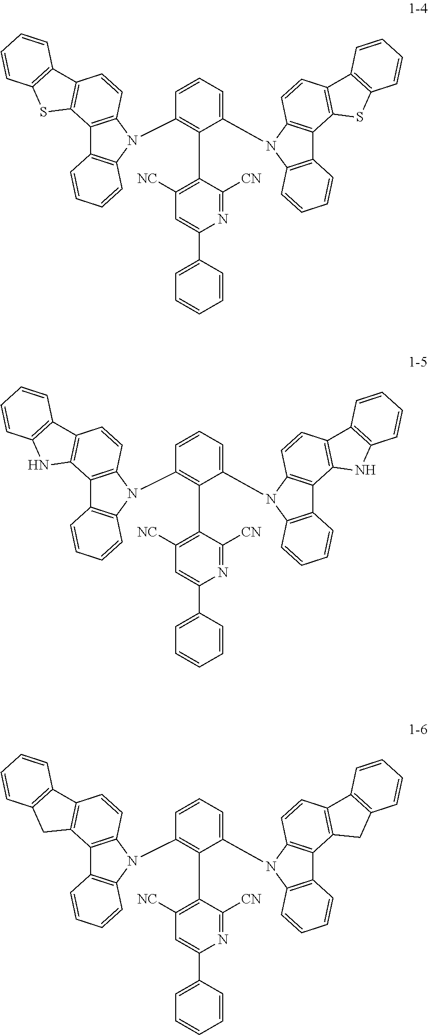 [SMILES: N#Cc1cc(-c2ccccc2)nc(C#N)c1-c1c(-n2c3ccccc3c3c4sc5ccccc5c4ccc32)cccc1-n1c2ccccc2c2c3sc4ccccc4c3ccc21 ; N#Cc1cc(-c2ccccc2)nc(C#N)c1-c1c(-n2c3ccccc3c3c4[nH]c5ccccc5c4ccc32)cccc1-n1c2ccccc2c2c3[nH]c4ccccc4c3ccc21 ; N#Cc1cc(-c2ccccc2)nc(C#N)c1-c1c(-n2c3ccccc3c3c4c(ccc32)-c2ccccc2C4)cccc1-n1c2ccccc2c2c3c(ccc21)-c1ccccc1C3]

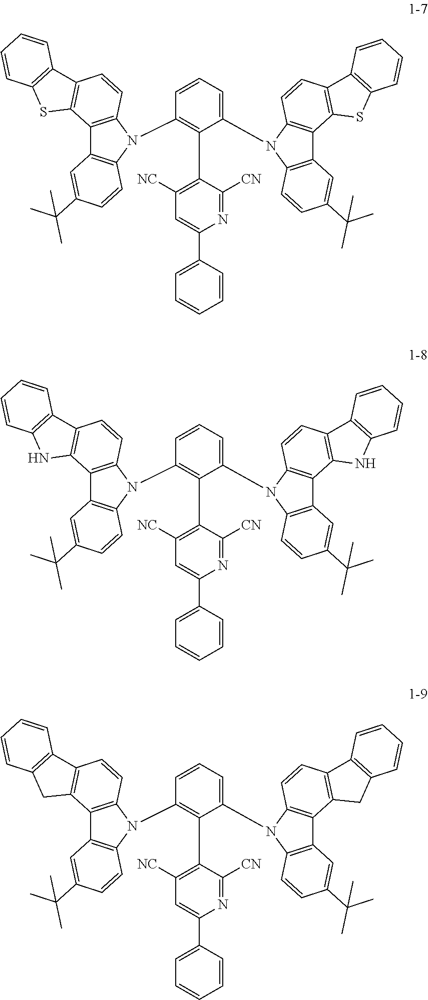 [SMILES: CC(C)(C)c1ccc2c(c1)c1c3sc4ccccc4c3ccc1n2-c1cccc(-n2c3ccc(C(C)(C)C)cc3c3c4sc5ccccc5c4ccc32)c1-c1c(C#N)cc(-c2ccccc2)nc1C#N ; CC(C)(C)c1ccc2c(c1)c1c3[nH]c4ccccc4c3ccc1n2-c1cccc(-n2c3ccc(C(C)(C)C)cc3c3c4[nH]c5ccccc5c4ccc32)c1-c1c(C#N)cc(-c2ccccc2)nc1C#N ; CC(C)(C)c1ccc2c(c1)c1c3c(ccc1n2-c1cccc(-n2c4ccc(C(C)(C)C)cc4c4c5c(ccc42)-c2ccccc2C5)c1-c1c(C#N)cc(-c2ccccc2)nc1C#N)-c1ccccc1C3]

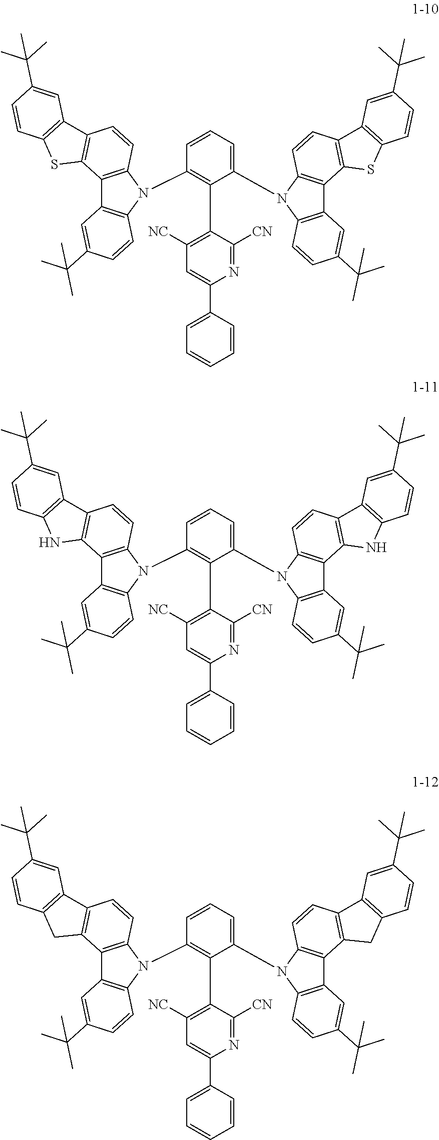

In the first compound 340a of delayed fluorescent material, excited triplet exciton can be converted upwardly its excited singlet exciton by RISC so that the first compound 340a can exhibit beneficial quantum efficiency. On the contrary, the first compound 340a has a distorted chemical conformation owing to the binding structure between the electron donor and the electron acceptor. In addition, the first compound 340a utilizes triplet excitons so that addition charge transfer transition (CT transition) can be included in the first compound 340a. The first compound 340a having the structure of Chemical Formulae 1 to 6 has wide full-width at half maximum (FWHM) caused by the luminous property owing to the CT luminous mechanism so that the first compound 340a has limited property in terms of color purity.

When the EML 340 include only the first compound 340a as emitter, the triplet exciton energy of the first compound 340a cannot contribute to the final light emission. In addition, the luminous lifespan of the organic light emitting diode can be lowered owing quenching process such as triplet-triplet annihilation (TTA) and triplet-polaron-annihilation (TPA).

The EML 340 includes the second compound 340b of fluorescent material in order to maximize the luminous properties of the first compound 340a of delayed fluorescent material and to realize hyper-fluorescence. As described above, the first compound 340a of delayed fluorescent material can utilize both the singlet exciton energy and the triplet exciton energy. When the EML 340 includes the second compound 340b of fluorescent material having appropriate energy level compared to the first compound 340a of delayed fluorescent material, the second compound 340b absorbs exciton energy released from the first compound 340a and the exciton energy absorbed by the second compound 340b can generate 100% singlet exciton with maximizing luminous efficiency.

The excited singlet exciton energy, including the singlet exciton energy converted upwardly from the excited triplet exciton and the initial singlet exciton energy, of the first compound 340a can be transferred to the second compound 340b of fluorescent material in the same emitting material layer mainly by Forster resonance energy transfer (FRET) mechanism, and the final light emission is occurred at the second compound 340b. As an example, an organic compound with large overlapping area of absorption wavelength with respect to the luminescence wavelength of the first compound 340a can be used as the second compound 340b so as to transfer efficiently exciton energy released from the first compound 340a to the second compound 340b. The ultimate emitting second compound 340b has beneficial color purity and luminous lifespan so that the color purity and luminous lifespan of the OLED D1 can be improved. As an example, the first compound 340a can have, but is not limited to, maximum photoluminescence (PL) wavelength between about 510 nm and about 540 nm.

As an example, the second compound 340b in the EML 340 can be green fluorescent material. For example, the second compound 340b in the EML 340 can be boron-based fluorescent material having FWHM of about 35 nm or less. In one example embodiment, the second compound 340b can include an organic compound having the following structure of Chemical Formula 7.

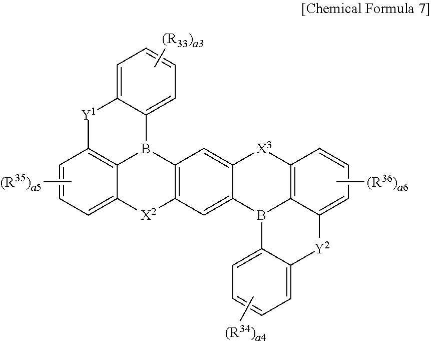

wherein, in the Chemical Formula 7,
Y¹ is O or NR³¹;
Y² is O or NR³²;
X² is O or NR³⁷;
X³ is O or NR³⁸;
each of R³¹ to R³⁸ is independently a hydrogen atom, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group, where each R³³ is identical to or different from each other when a3 is 2, 3 or 4, each R³⁴ is identical to or different from each other when a4 is 2, 3 or 4, each R³⁵ is identical to or different from each other when a5 is 2 or 3, and each R³⁶ is identical to or different from each other when a6 is 2 or 3, or
optionally,
R³¹ and R³³, R³¹ and R³⁵, R³⁵ and R³⁷, R³⁷ and R³⁴, R³⁴ and R³², R³² and R³⁶, R³⁶ and R³⁸ and/or R³⁸ and R³³ are linked together to form an unsubstituted or substituted hetero aromatic ring including a nitrogen atom or an oxygen atom;
each of a3 and a4 is independently 0, 1, 2, 3 or 4; and
each of a5 and a6 is independently 0, 1, 2 or 3.

As an example, each of R³¹ to R³⁸ in Chemical Formula 7 can be independently a C₁-C₂₀ alkyl group (e.g., methyl, isopropyl and/or tert-butyl) or an unsubstituted or C₁-C₂₀ alkyl (e.g., methyl, isopropyl and/or tert-butyl) substituted C₆-C₃₀ aryl group (e.g., phenyl). Alternatively, R³¹ and R³³, R³¹ and R³⁵, R³² and R³⁴ and/or R³² and R³⁶ can be linked together to form a hetero aromatic ring including the nitrogen atom or the oxygen atom. Each of a3, a4, a5 and a6 in Chemical Formula 7 can be independently 0, 1, 2 or 3 when those groups are not the hydrogen atom.

In one example embodiment, each of X² and X³ in Chemical Formula 7 can be independently an oxygen atom. In another example embodiment, X² and X³ in Chemical Formula 7 can be NR³⁷ and NR³⁸, respectively, where each of R³⁷ and R³⁸ can be independently a C₆-C3o aryl group (e.g., phenyl) unsubstituted or substituted with at least one C₁-C₂₀ alkyl group (e.g., methyl, iso-propyl, and/or tert-butyl).

In one example embodiment, Y¹ and Y² in Chemical Formula 7 can be NR³¹ and NR³², respectively, where each of R³¹ and R³² can be independently a C₆-C₃₀ aryl group (e.g., phenyl) unsubstituted or substituted with at least one C₁-C₂₀ alkyl group (e.g., methyl, isopropyl and/or tert-butyl). Alternatively, R³¹ and R³³, R³¹ and R³⁵, R³² and R³⁴ and/or R³² and R³⁶ can be linked together to form an unsubstituted or substituted C₃-C₃₀ hetero aromatic ring. For example, R³¹ and R³³, R³¹ and R³⁵, R³² and R³⁴ and/or R³² and R³⁶ can be linked together to form an unsubstituted or substituted carbazole ring

As an example, the second compound 340b having the structure of Chemical Formula 7 can be, but is not limited to, at least one of the following organic compounds of Chemical Formula 8:

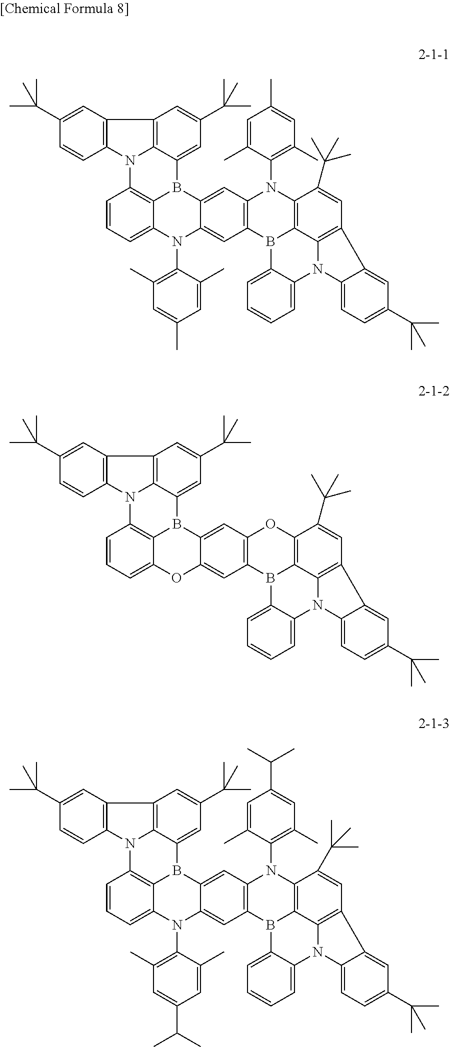

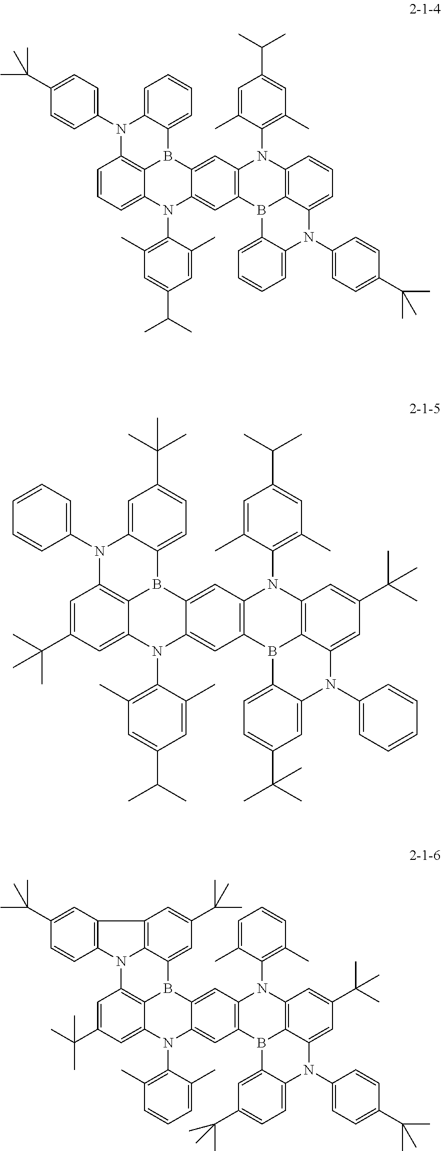

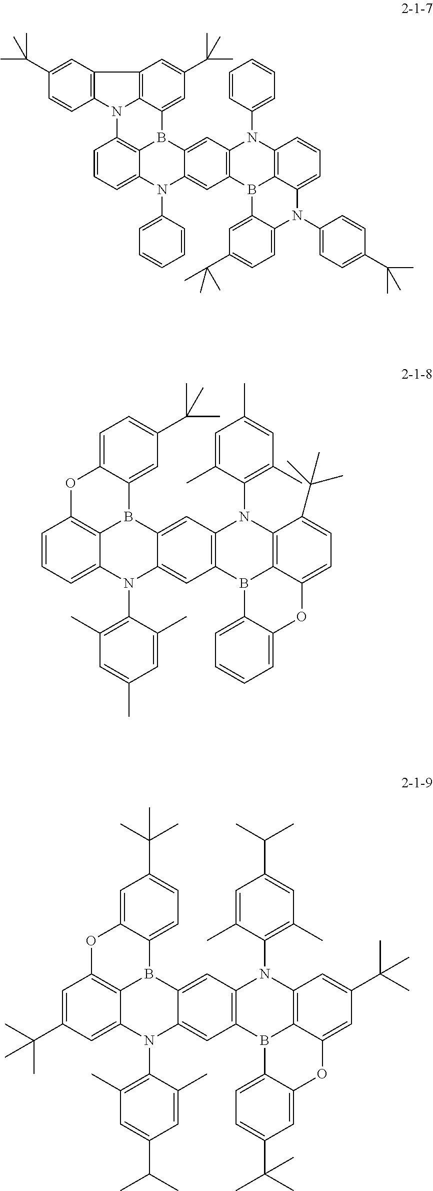

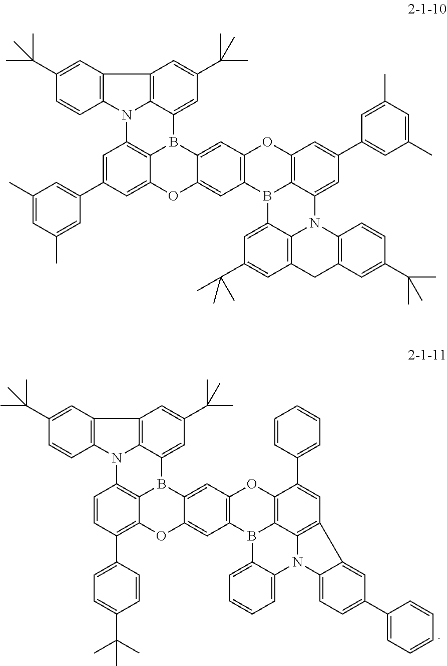

In another example embodiment, the second compound 340b can include an organic compound having the following structure of Chemical Formula 9:

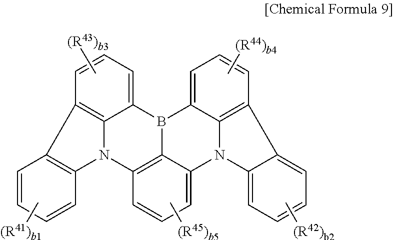

wherein, in the Chemical Formula 9,
each of R⁴¹ to R⁴⁴ is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group, where each R⁴¹ is identical to or different from each other when b 1 is 2, 3 or 4, each R⁴² is identical to or different from each other when b2 is 2, 3 or 4, each R⁴³ is identical to or different from each other when b3 is 2 or 3, and each R⁴⁴ is identical to or different from each other when b4 is 2 or 3, or
optionally,
two adjacent R⁴¹ when b1 is 2, 3 or 4, two adjacent R⁴² when b2 is 2, 3 or 4, two adjacent R⁴³ when b3 is 2 or 3 and/or two adjacent R⁴⁴ when b4 is 2 or 3 are linked together to form an unsubstituted or substituted C₆-C₂₀ aromatic ring or an unsubstituted or substituted C₃-C₂₀ hetero aromatic ring;
R⁴⁵ is an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group, where each R⁴⁵ is identical to or different from each other when b5 is 2 or 3, or
optionally,
two adjacent R⁴⁵ when b5 is 2 or 3 are linked together to form an unsubstituted or substituted C₆-C₂₀ aromatic ring or an unsubstituted or substituted C₃-C₂₀ hetero aromatic ring;
each of b1 and b2 is independently 0, 1, 2, 3 or 4; and
each of b3, b4 and b5 is independently 0, 1, 2 or 3.

As an example, each of R⁴¹ to R⁴⁴ in Chemical Formula 9 can be independently a C₁-C₂₀ alkyl group (e.g., methyl, isopropyl and/or tert-butyl) and R⁴⁵ can be an unsubstituted or C₁-C₂₀ alkyl (e.g., methyl, isopropyl and/or tert-butyl), for example, at least one C₁-C₂₀ alkyl (e.g., two, three or four alkyl) substituted C₃-C₃₀ hetero aryl group (e.g., carbazolyl). Alternatively, two adjacent R⁴⁵ in Chemical Formula 9 can be linked together to form a fused C₃-C₂₀ hetero aryl ring (e.g., quinoline ring or isoquinoline ring) unsubstituted or substituted with a C₁-C₁₀ alkyl group (e.g., methyl, isopropyl and/or tert-butyl). In another example embodiment, each of b 1 , b2, b3 and b4 in Chemical Formula 9 can be independently 1 and b5 can be 1 or 2.

For example, the second compound 340b having the structure of Chemical Formula 9 can be, but is not limited to, at least one of the following organic compounds of Chemical Formula 10:

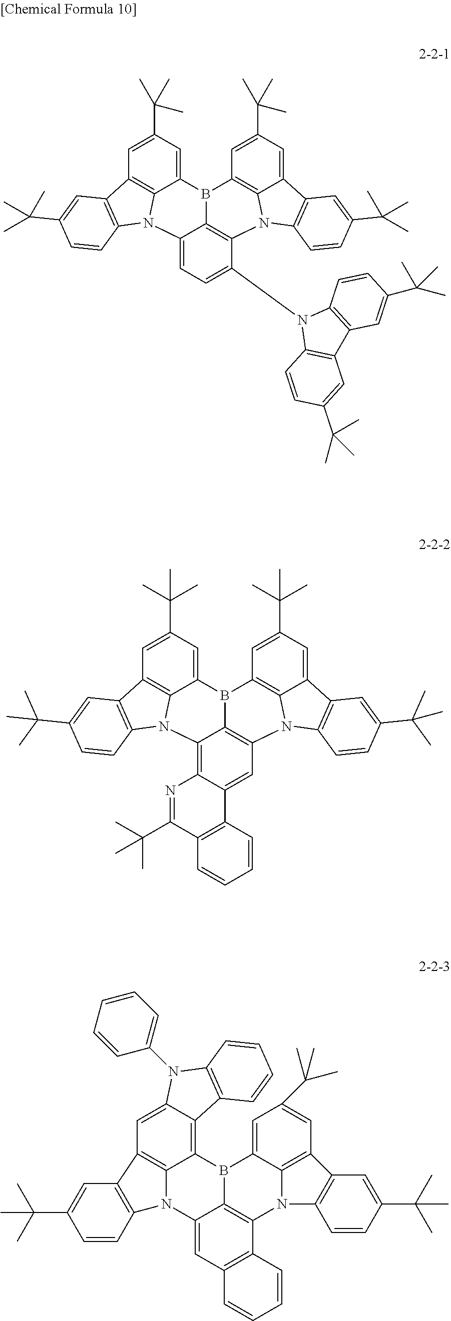

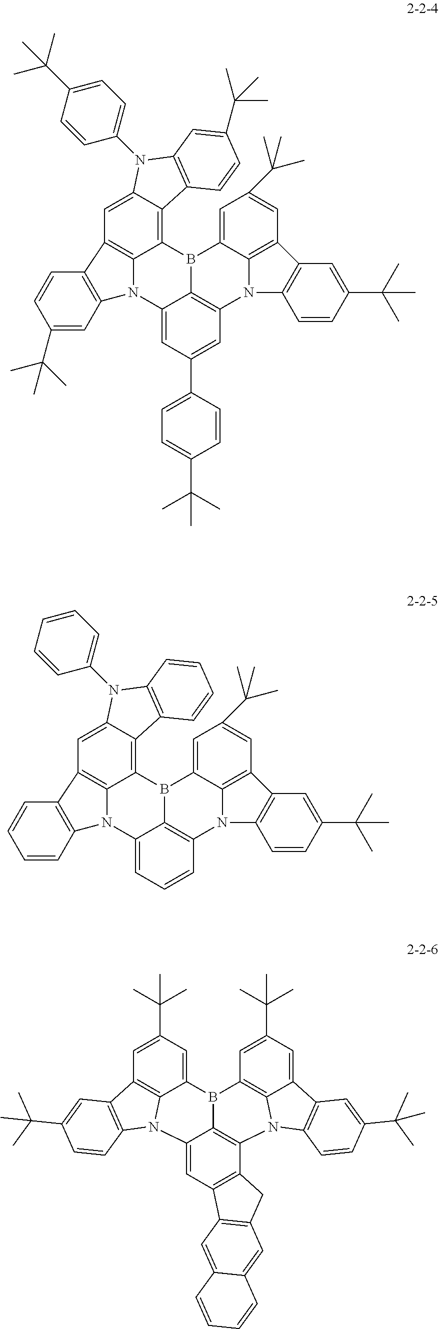

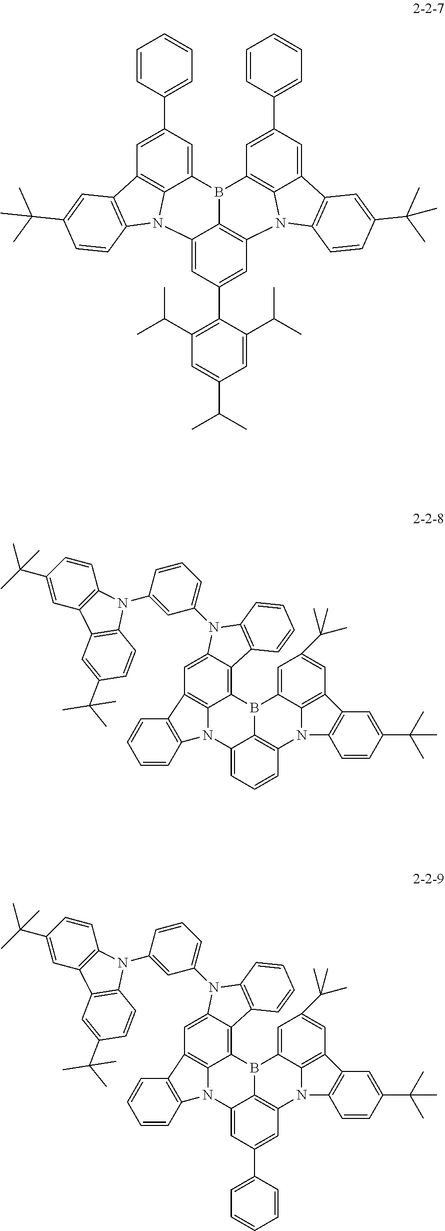

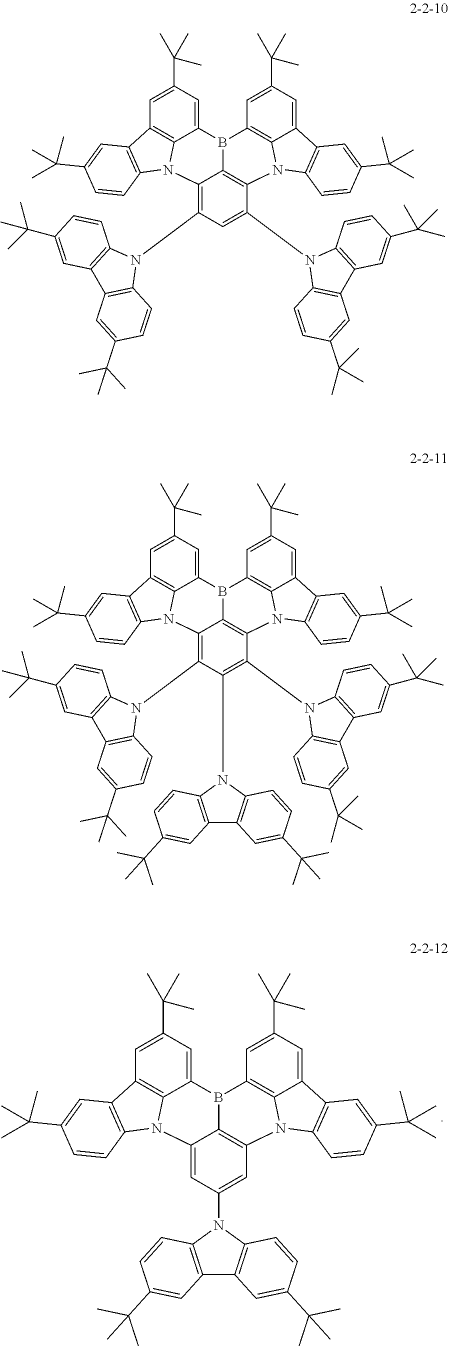

The second compound 340b of the boron-based compound having the structure of Chemical Formulae 7 to 10 exhibits beneficial luminous properties. The second compound 340b of the boron-based compound having the structure of Chemical Formula 7 to 10 has a wide plate-like structure so that the second compound 340b can receive efficiently exciton energy released from the first compound 340a, and therefore, the luminous efficiency of the OLED D1 can be maximized.

The third compound 340c in the EML 340 can include any organic compound where the energy bandgap E_{g} between the HOMO energy level and the LUMO energy level is wider than the energy bandgap between the HOMO energy level and the LUMO energy level of the first compound 340a and/or the second compound 340b. When the EML 340 includes the third compound 340c of the host, the first compound 340a can be a first dopant (auxiliary dopant) and the second compound 340b can be a second dopant.

As an example, the third compound 340c can include a P-type green host with relatively strong hole affinity and/or an N-type green host with relatively strong electron affinity. For example, the P-type green host can include, but is not limited to, a biscarbazole-based organic compound, an aryl amine- and/or a hetero aryl amine-based organic compound with at least one fused aromatic moiety and/or fused hetero aromatic moiety, and/or an aryl amine- and/or hetero aryl amine-based organic compound with a spirofluorenen moiety. The N-type green host can include, but is not limited to, an azine-based organic compound.

In one example embodiment, the third compound 340c can include, but is not limited to, an organic compound having the following structure of Chemical Formula 11:

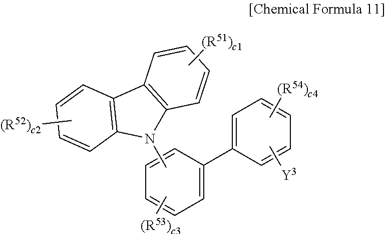

wherein, in the Chemical Formula 11,
each of R⁵¹ and R⁵² is independently an unsubstituted or substituted C₁-C₂₀ alkyl group, an unsubstituted or substituted C₆-C₃₀ aryl group or an unsubstituted or substituted C₃-C₃₀ hetero aryl group, where each R⁵¹ is identical to or different from each other when c1 is 2, 3 or 4, and where each R⁵² is identical to or different from each other when c2 is 2, 3 or 4;
each of R⁵³ and R⁵⁴ is independently an unsubstituted or substituted C₁-C₂₀ alkyl group, an unsubstituted or substituted C₆-C₃₀ aryl group or an unsubstituted or substituted C₃-C₃₀ hetero aryl group, or
optionally, R⁵³ and R⁵⁴ are linked together to form an unsubstituted or substituted hetero ring, where each R⁵³ is identical to or different from each other when c3 is 2, 3 or 4, and where each R⁵⁴ is identical to or different from each other when c4 is 2, 3 or 4;
Y³ has the following structure of Chemical Formula 12 or Chemical Formula 13;
each of c1 , c2, c3 and c4 is independently 0, 1, 2, 3 or 4,

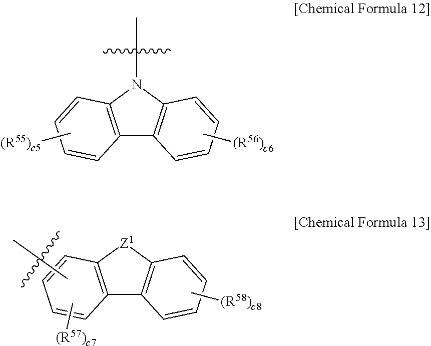

wherein, in the Chemical Formulae 12 and 13,
each of R⁵⁵, R⁵⁶, R⁵⁷ and R⁵⁸ is independently an unsubstituted or substituted C₁-C₂₀ alkyl group, an unsubstituted or substituted C₆-C₃₀ aryl group or an unsubstituted or substituted C₃-C₃₀ hetero aryl group, where each R⁵⁵ is identical to or different from each other when c5 is 2, 3 or 4, each R⁵⁶ is identical to or different from each other when c6 is 2, 3 or 4, each R⁵⁷ is identical to or different from each other when c7 is 2 or 3, and each R⁵⁸ is identical to or different from each other when c8 is 2, 3 or 4;
each of c5, c6 and c8 is independently 0, 1, 2, 3 or 4;
c7 is 0, 1, 2 or 3; and
Z¹ is NR⁵⁹, O or S, where R⁵⁹ is a hydrogen atom, an unsubstituted or substituted C₁-C₂₀ alkyl group, an unsubstituted or substituted C₆-C₃₀ aryl group or an unsubstituted or substituted C₃-C₃₀ hetero aryl group.

As an example, the third compound 340c can include, but is not limited to, at least one of the following organic compound of Chemical Formula 14:

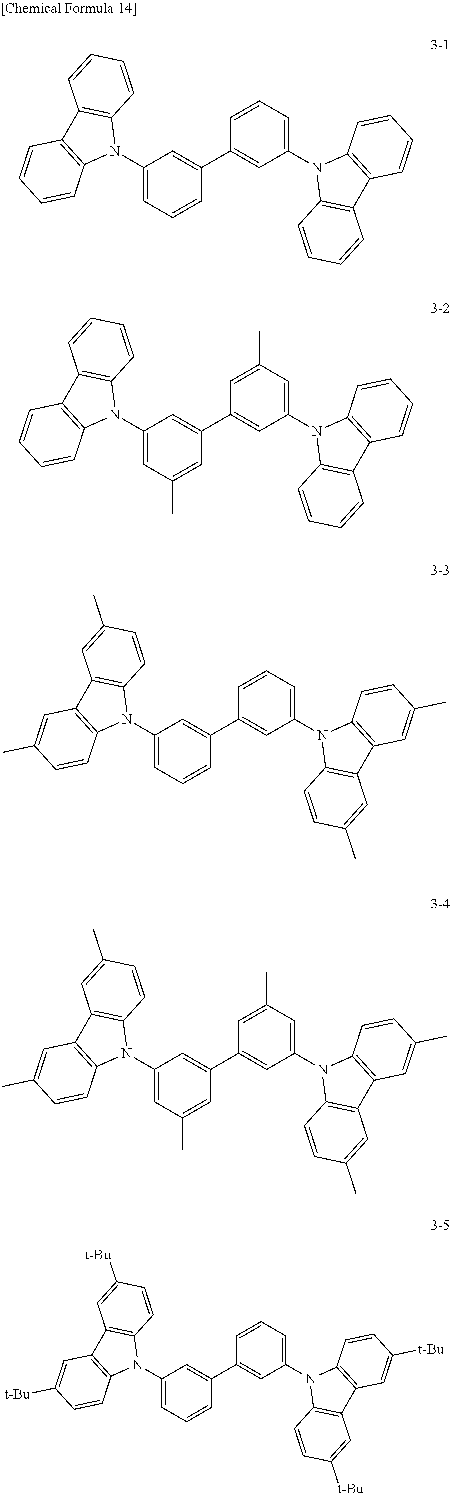

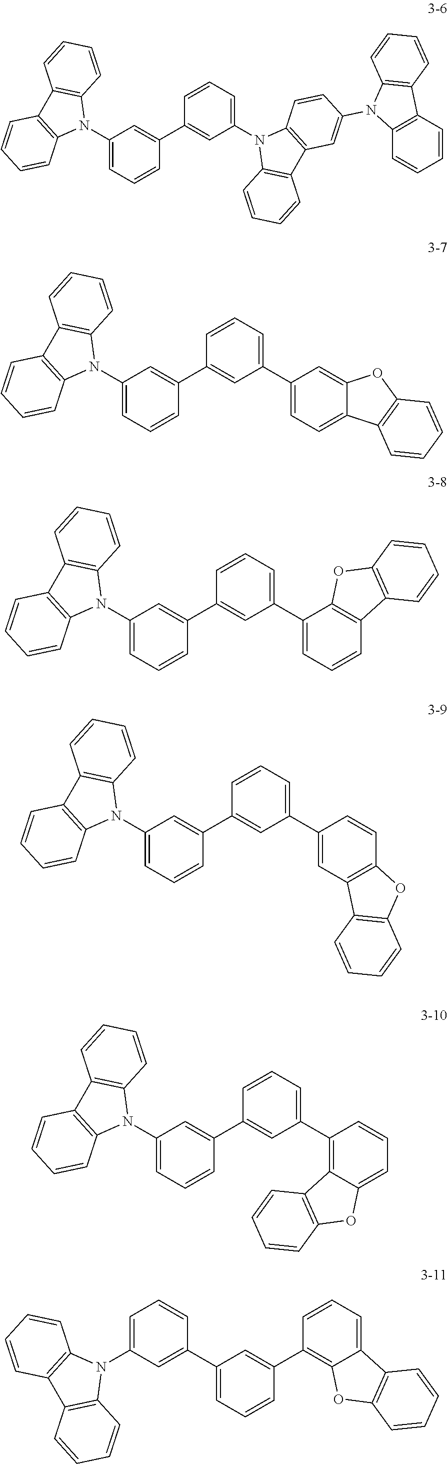 [SMILES: c1cc(-c2cccc(-n3c4ccccc4c4cc(-n5c6ccccc6c6ccccc65)ccc43)c2)cc(-n2c3ccccc3c3ccccc32)c1 ; c1cc(-c2cccc(-n3c4ccccc4c4ccccc43)c2)cc(-c2ccc3c(c2)oc2ccccc23)c1 ; c1cc(-c2cccc(-n3c4ccccc4c4ccccc43)c2)cc(-c2cccc3c2oc2ccccc23)c1 ; c1cc(-c2cccc(-n3c4ccccc4c4ccccc43)c2)cc(-c2ccc3oc4ccccc4c3c2)c1 ; c1cc(-c2cccc(-n3c4ccccc4c4ccccc43)c2)cc(-c2cccc3oc4ccccc4c23)c1 ; c1cc(-c2cccc(-n3c4ccccc4c4ccccc43)c2)cc(-c2cccc3c2oc2ccccc23)c1]

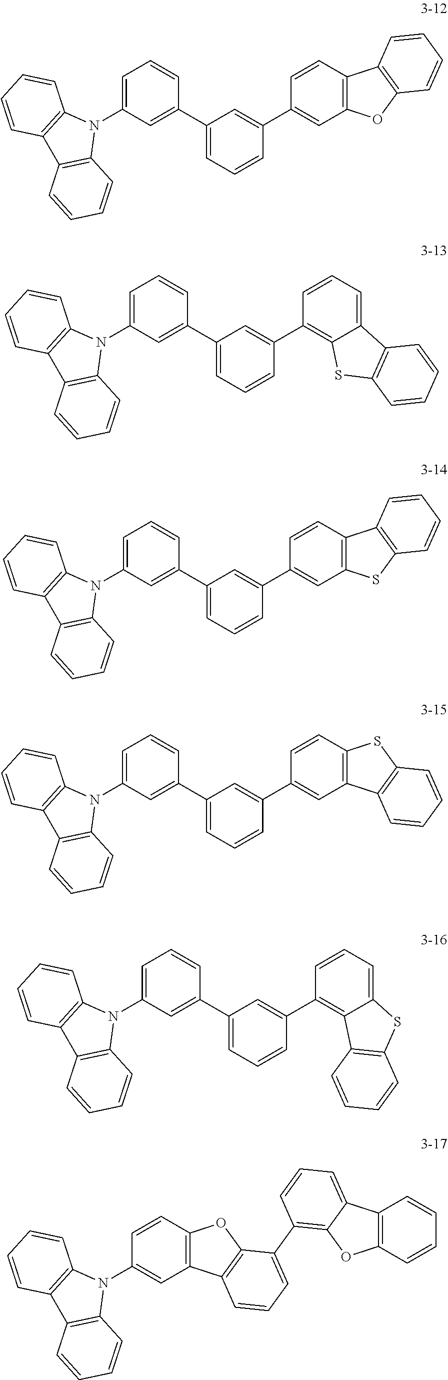 [SMILES: c1cc(-c2cccc(-n3c4ccccc4c4ccccc43)c2)cc(-c2ccc3c(c2)oc2ccccc23)c1 ; c1cc(-c2cccc(-n3c4ccccc4c4ccccc43)c2)cc(-c2cccc3c2sc2ccccc23)c1 ; c1cc(-c2cccc(-n3c4ccccc4c4ccccc43)c2)cc(-c2ccc3c(c2)sc2ccccc23)c1 ; c1cc(-c2cccc(-n3c4ccccc4c4ccccc43)c2)cc(-c2ccc3sc4ccccc4c3c2)c1 ; c1cc(-c2cccc(-n3c4ccccc4c4ccccc43)c2)cc(-c2cccc3sc4ccccc4c23)c1 ; c1ccc2c(c1)oc1c(-c3cccc4c3oc3ccc(-n5c6ccccc6c6ccccc65)cc34)cccc12]

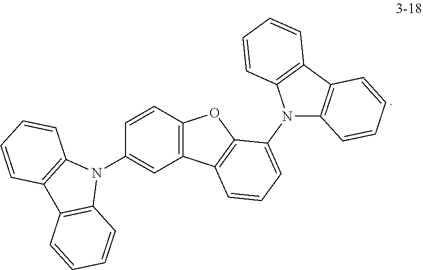 [SMILES: c1cc(-n2c3ccccc3c3ccccc32)c2oc3ccc(-n4c5ccccc5c5ccccc54)cc3c2c1]

In another example embodiment, the third compound 340c in the EML 340 can include, but is not limited to, 9-(3-(9H-carbazol-9-yl)phenyl)-9H-carbazole-3-carbonitrile (mCP-CN), CBP, 3,3′-bis(N-carbazolyl)-1,1′-bipheny (mCBP), 1,3-B is(carbazol-9-yl)benzene (mCP), B is [2-(diphenylphosphino)phenyl]ether oxide (DPEPO), 2,8- bis(diphenylphosphoryl)dibenzothiophene (PPT), 1,3,5-Tri [(3-pyridyl)-phen-3-yl] benzene (TmPyPB), 2,6-Di(9H-carbazol-9-yl)pyridine (PYD-2Cz), 2,8-di(9H-carbazol-9-yl)dibenzothiophene (DCzDBT), 3′,5′-Di(carbazol-9-yl)-[1,1′-biphenyl] -3,5-dic arbonitrile (DCzTPA), 4′-(9H-carbazol-9-yl)biphenyl-3,5-dicarbonitrile(4′-(9H-carbazol-9-yl)biphenyl-3,5-dicarbonitrile (pCzB -2CN), 3′-(9H-carbazol-9-yl)biphenyl-3 ,5-dic arbonitrile (mCzB-2CN), Diphenyl-4-triphenylsilyl- phenylphosphine oxide (TSP01), 9-(9-phenyl-9H-carbazol-6-yl)-9H-carbazole (CCP), 4-(3-(triphenylen-2-yl)phenyl)dibenzo [b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicarbazole, 9,9′-Diphenyl-9H,9′H-3,3′-bicarbazole (BCzPh), 1,3,5-Tris(carbazole-9-yl)benzene (TCP), Tris(4-carbazoyl-9-yl-phenyl)amine (TCTA), 4,4′-Bis(carbazole-9-yl)-2,2′-dimethylbiphenyl (CDBP), 2,7-B is (carbazole-9-yl)-9,9-dimethylfluorene (DMFL-CBP), 2,2′,7,7′-Tetrakis(carbazole-9-yl)-9,9-spirofluorene (Spiro-CBP), 3,6-Bis(carbazole-9-yl)-9-(2-ethyl-hexyl)-9H-carbazole (TCz1) and/or combinations thereof.

In one example embodiment, the contents of the third compound 340c in the EML 340 can be larger than the contents of the first compound 340a, and the contents of the first compound 340a in the EML 340 can be larger than the contents of the second compound 340b. In this case, exciton energy can be transferred sufficiently from the first compound 340a to the second compound 340b by FRET mechanism. As an example, the contents of the third compound 340c in the EML 340 can be about 55 wt % to about 85 wt %, the contents of the first compound 340a can be about 10 wt % to about 40 wt %, for example, about 10 wt % to about 30 wt %, and the contents of the second compound 340b can be about 0.1 wt % to about 5 wt %, for example, about 0.1 wt % to about 2 wt %, but is not limited thereto.

The first compound 340a shows large steric hindrance owing to multiple electron donor moieties. In the first compound 340a, RISC can be occurred rapidly by controlling HOMO and LUMO energy levels and maximizing intra-molecular charge transfer efficiency. The triplet exciton generated initially at the first compound 340a can be converted upwardly to its singlet exciton by RISC without transferring to the second compound 340b. The singlet exciton generated at the first compound 340a is transferred rapidly to the second compound 340b through FRET mechanism.

In other words, the triplet excitons generated at the first compound 340a are converted to its singlet excitons, and then the singlet excitons of the first compound 340a can be transferred rapidly to the second compound 340b. As exciton energy can be transferred efficiently from the first compound 340a to the second compound 340b, the luminous efficiency of the OLED D1 can be maximized.

In addition, the HOMO energy levels and the LUMO energy levels among the first compound 340a of delayed fluorescent material, the second compound 340b of fluorescent material and the third compound 340c can be property adjusted. For example, the third compound 340c should induce the triplet excitons generated at the first compound 340a to contribute emission without quenching (non-emission) in order to realize hyper-fluorescence.

The third compound 340c can have HOMO energy level lower than HOMO energy level of the first compound 340a, and have LUMO energy level higher than LUMO energy level of the first compound 340a. In other words, the energy bandgap between HOMO energy level and the LUMO energy level of the third compound 340c can be wider than the energy bandgap between the HOMO energy level and the LUMO energy level of the first compound 340a.

As an example, energy bandgap between the LUMO energy level of the first compound 340a and the LUMO energy level of the third compound 340c can be narrower than energy bandgap between the HOMO energy level of the first compound 340a and the HOMO energy level of the third compound 340c. In other words, electron energy barrier between the first compound 340a and the third compound 340c can be lower than hole energy barrier between the first compound 340a and the third compound 340c.

Generally, holes can be injected into an emitting material layer faster than electrons in an organic light emitting diode so that charge unbalance can be caused in the emitting material layer. A portion of relatively more injected holes cannot recombine with electrons and annihilated without excitons. In this case, the luminous efficiency and luminous lifespan of the organic light emitting diode can be lowered owing to the holes not recombined with electrons cause stress at the luminous materials or hole transporting materials.

On the contrary, the electron transport barrier is designed to be lower than the hole transport barrier so that holes and electrons can be transferred in balance to the second compound 340b through the first compound 340a. The luminous efficiency and the luminous lifespan of the OLED D1 can be further improved.

In one example embodiment, the first compound 340a can have, but is not limited to, the HOMO energy level between about −5.2 eV and about −5.4 eV and the LUMO energy level between about −2.3 eV and about −2.5 eV. The third compound 340c can have, but is not limited to, the HOMO energy level between about −5.8 eV and about −6.1 eV and the LUMO energy level between about −2.1 eV and about −2.9 eV.

When the EML 340 includes the first compound 340a and the second compound 340b of which the photoluminescence wavelengths, the absorption wavelengths, the HOMO energy levels and/or the LUMO energy levels are adjusted, 100% internal quantum efficiency using RISC mechanism can be realized since excitons are recombined at the first compound 340a of delayed fluorescent material. The singlet exciton energy generated at the first compound 340a by RISC mechanism is transferred to the second compound 340b of fluorescent material by FRET mechanism. Effective light emission is occurred at the second compound 340b so that the OLED D1 with beneficial color purity can be realized.

In another example embodiment, each of the excited triplet energy level and/or the excited singlet energy level of the third compound 340c can be higher than each of the excited triplet energy level and/or the excited singlet energy level of the first compound 340a, respectively. For example, the excited triplet energy level of the third compound 340c can be higher than the excited triplet energy level of the first compound 340a by about 0.2 eV or more, for example, about 0.3 eV or more or about 0.5 eV or more.

When the excited triplet energy level and/or the excited singlet energy level of the third compound 340c is not higher sufficiently than the excited triplet energy level and/or the excited singlet energy level of the first compound 340a, the excitons at the excited triplet energy level of the first compound 340a can be reversely transferred to the excited triplet energy level of the third compound 340c. As the triplet excitons are quenched at the third compound 340c that cannot utilize the triplet excitons, the triplet excitons of the first compound 340a of delayed fluorescent material cannot contribute to light emission. As an example, the energy bandgap ΔE_{ST} between the excited singlet energy level and the excited triplet energy level of the first compound can be about 0.3 eV or less, for example, between about 0.05 eV and about 0.3 eV.

In addition, exciton energy should be transferred from the first compound 340a of delayed fluorescent material that is transformed to ICT complex state by RISC mechanism to the second compound 340b of fluorescent material in the EML 340 so that the OLED D1 having high efficiency and high color purity can be implemented. As an example, the excited singlet energy level of the first compound 340a of delayed fluorescent material can be higher than the excited singlet energy level of the second compound 340b of fluorescent material. Alternatively, the excited triplet energy level of the first compound 340a can be higher than the excited triplet energy level of the second compound 340b.

The second compound 340b can utilize both the singlet exciton energy and the triplet exciton energy of the first compound during light emission so that the luminous efficiency of the OLED D1 can be maximized. In addition, exciton quenching such as triplet-triplet annihilation (TTA) and triplet-polaron annihilation (TPA) is minimized so that the luminous lifespan of the OLED D1 can be improved significantly.

The HIL 310 is disposed between the first electrode 210 and the HTL 320 and can improve an interface property between the inorganic first electrode 210 and the organic HTL 320. In one example embodiment, the HIL 310 can include, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), TCTA, N,N′- Diphenyl-N,N′-bis(1-naphthyl)-1,1′-biphenyl-4,4″-diamine (NPB; NPD), N,N′-{4-[bis(3-methylphenyl)amino]phenyl}-N,N′-diphenul-4,4′-biphenyldiamine (DNTPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 2,3,5,6-Tetrafluoro-7,7,8,8-tetracy ano-quinodimethane (F4-TCNQ), 1,3,4,5,7,8-hexalliuototcracvalrionvilthoquirtodintut1 ane (F6-TCNNQ), 1,3,5-tris [4-(diphenylamino)phenyl]b enzene (TDAPB), poly (3,4-ethylenedioxythiphene)poly s tyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl- amino)phenyl]benzidine (NPNPB) and/or combinations thereof.

Alternatively, the HIL 310 can include hole transporting material, as described below, doped with the hole injecting material (e.g., HAT-CN, F4-TCNQ and/or F6-TCNNQ). In this case, the contents of the hole injecting material in the HIL 310 can be, but is not limited to, about 2 wt % to about 15 wt %. The HIL 310 can be omitted in compliance of the OLED Dl.

The HTL 320 is disposed between the HIL 310 and the EML 340. In one example embodiment, the HTL 320 can include, but is not limited to, N,N′-Diphenyl-N,N′-bis(3-methylphenyl)-1,1′-biphenyl-4,4′-diamine (TPD), NPB(NPD), DNTPD, CBP, Poly [N,N′-bis(4-butylphenyl)-N,N′-bis(phenyl)-benzidine] (Poly-TPD), Poly [(9,9-dioctylfluorenyl-2,7-diyl)-co-(4,4′-(N-(4-sec-butylphenyl)diphenylamine))] (TFB), Di-[4-(N,N-di-p-tolyl-amino)-phenyl]cyclohexane (TAPC), 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3 -yl)phenyl)biphenyl-4-amine), N-([1,1′-Biphenyl]-4-yl)-9,9-dimethyl-N-(4-(9-phenyl-9H-carbazol-3 -yl)phenyl)-9H-fluoren-2-amine and/or combinations thereof.

The ETL 360 and the EIL 370 can be laminated sequentially between the EML 340 and the second electrode 230. An electron transporting material included in the ETL 360 has high electron mobility so as to provide electrons stably with the EML 340 by fast electron transportation. In one example embodiment, the ETL 360 can include at least one of an oxadiazole-based compound, a triazole-based compound, a phenanthroline-based compound, a benzoxazole-based compound, a benzothiazole-based compound, a benzimidazole-based compound and a triazine-based compound.

More particularly, the ETL 360 can include, but is not limited to, tris-(8-hydroxyquinoline) aluminum (Alq₃), 2-biphenyl-4-yl-5-(4-t-butylphenyl)-1,3,4-oxadiazole (PBD), spiro-PBD, lithium quinolate (Liq), 1,3,5-Tris(N-phenylbenzimidazol-2-yl)benzene (TPBi), Bis(2-methyl-8-quinolinolato-N1,08)-(1,1′-biphenyl-4-olato)aluminum (B Alq), 4,7-diphenyl-1,10-phenanthroline (Bphen), 2,9-B is (naphthalene-2-yl)4,7-diphenyl-1,10-phenanthroline (NBphen), 2,9-Dimethyl-4,7-diphenyl-1,10-phenathroline (B CP), 3-(4-B iphenyl)-4-phenyl-5-tert-butylphenyl-1,2,4-triazole (TAZ), 4-(Naphthalen-l-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3 -y1)1,3 ,5-triazine (TmPPPyTz), Poly [9,9-bis (3′-((N,N-dimethyl)-N-ethylammonium)-propyl)-2,7-fluorene]-alt-2,7-(9,9-dioctylfluorene)] (PFNBr), tris(phenylquinoxaline (TPQ), TSPO1, 2- [4-(9,10-Di-2-naphthalen2-yl-2-anthracen-2-yl)phenyl]-1-phenyl-1H-benzimidazole (ZADN) and/or combinations thereof.

The EIL 370 is disposed between the second electrode 230 and the ETL 360, and can improve physical properties of the second electrode 230 and therefore, can enhance the lifespan of the OLED D1. In one example embodiment, the EIL 370 can include, but is not limited to, an alkali metal halide or an alkaline earth metal halide such as LiF, CsF, NaF, BaF2 and the like, and/or an organometallic compound such as Liq, lithium benzoate, sodium stearate, and the like. Alternatively, the EIL 370 can be omitted.

When holes are transferred to the second electrode 230 via the EML 340 and/or electrons are transferred to the first electrode 210 via the EML 340, the luminous lifespan and the luminous efficiency of the OLED D1 can be lowered. In order to prevent those phenomena, the OLED D1 in accordance with this aspect of the present disclosure can have at least one exciton blocking layer adjacent to the EML 340.

As an example, the OLED D1 can include the EBL 330 between the HTL 320 and the EML 340 so as to control and prevent electron transportations. In one example embodiment, the EBL 330 can independently include, but is not limited to, TCTA, Tris[4-(diethylamino)phenyl]amine, N-(biphenyl-4-yl)-9,9-dimethyl-N-(4-(9-phenyl-9H-carbazol-3 -yl)phenyl)-9H-fluorene-2-amine, TAPC, MTDATA, mCP, mCBP, CuPc, DNTPD, TDAPB, DCDPA, 3,6-bis(N-carbazolyl)-N-phenyl-carbazole and/or combinations thereof.

In addition, the OLED D1 can further include the HBL 350 between the EML 340 and the ETL 360 so that holes cannot be transported from the EML 340 to the ETL 360. In one example embodiment, the HBL 350 can include, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound.

For example, the HBL 350 can include material having a relatively low HOMO energy level compared to the luminescent materials in the EML 340. The HBL 350 can include, but is not limited to, BCP, B Alq, Alq₃, PBD, spiro-PBD, Liq, Bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and/or combinations thereof.

In the above embodiment, the single-layered emitting material layer includes the first compound with delayed fluorescent properties and the second compound with fluorescent properties. The first compound and the second compound are introduced in separately disposed emitting material layers.

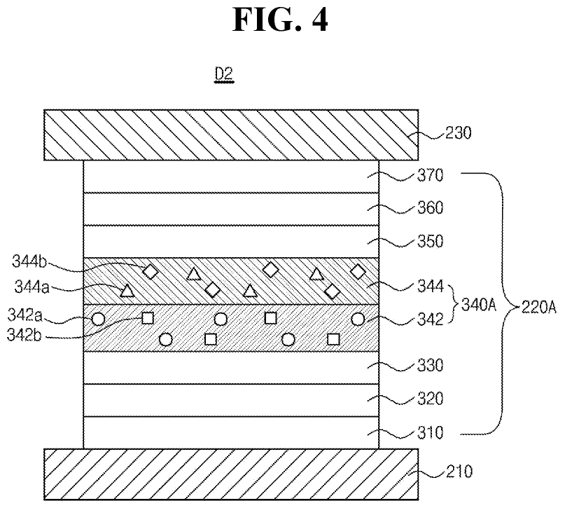

FIG. 4 illustrates a schematic cross-sectional view of an organic light emitting diode in accordance with another example embodiment of the present disclosure. As illustrated in FIG. 4, the OLED D2 in accordance with another example embodiment of the present disclosure includes a first electrode 210, a second electrode 230 facing the first electrode 210 and an emissive layer 220A disposed between the first and second electrodes 210 and 230. The organic light emitting display device 100 (FIG. 2) can include a red pixel region, a green pixel region and a blue pixel region and the OLED D2 can be located at the green pixel region.

The emissive layer 220A includes an emitting material layer (EML) 340A. The emissive layer 220A can include at least one of the HTL 320 disposed between the first electrode 210 and the EML 340A and the ETL 360 disposed between the EML 340A and the second electrode 230. The emissive layer 220A can further include at least one of the HIL 310 disposed between the first electrode 210 and the HTL 320 and the EIL 370 disposed between the ETL 360 and the second electrode 230. Alternatively, the emissive layer 220A can further include the EBL 330 disposed between the HTL 320 and the EML 340A and/or the HBL 350 disposed between the EML 340A and the ETL 360. The configurations of the first electrode 210, the second electrode 230 and the emissive layer 220A except the EML 340A can be identical to corresponding elements in the above embodiment.

The EML 340A include a first EML (EML1, lower EML, first layer) 342 disposed between the EBL 330 and the HBL 350 and a second EML (EML2, upper EML, second layer) 344 disposed between the EML1 342 and the HBL 350. Alternatively, the EML2 344 can be disposed between the EBL 330 and the EML1 342.

One of the EML1 342 and the EML2 344 includes a first compound (first dopant) 342a of delayed fluorescent material and the other of the EML1 342 and the EML2 344 includes a second compound (second dopant) 344a of fluorescent material. The EML1 342 and the EML2 344 can further include a third compound 342b of a first host and a fourth compound 344b of a second host, respectively. As an example, the EML1 342 can include the first compound 342a and the third compound 342b and the EML2 344 can include the second compound 344a and the fourth compound 344b.

The first compound 342a in the EML1 342 can be delayed fluorescent material having the structure of Chemical Formulae 1 to 6. The triplet exciton generated at the first compound 342a with delayed fluorescent properties can be converted upwardly to singlet exciton by RISC. While the first compound 342a has high internal quantum efficiency, the color purity of the first compound 342a is poor owing to wide FWHM.

The EML2 344 includes the second compound 344a of fluorescent material. The second compound 344a includes the organic compound having the structure of Chemical Formulae 7 to 10. The second compound 344a of fluorescent material having the structure of Chemical Formulae 7 to 11 has narrow FWHM (e.g., about 35 nm or less) compared to the first compound 342a. The second compound 344a has an advantage in terms of color purity.

The singlet exciton energy and the triplet exciton energy generated at the first compound 342a with delayed fluorescent properties in the EML1 342 are transferred to the second compound 344a in the EML2 344 disposed adjacently to the EML1 342 by FRET mechanism, and the ultimate light emission is occurred at the second compound 344a.

The triplet exciton energy of the first compound 342a in the EML1 342 is converted upwardly its singlet exciton energy by RISC. The singlet exciton energy of the first compound 342a is transferred to the excited singlet energy level of the second compound 344a. The second compound 344a in the EML2 344 can emit light with utilizing both the singlet exciton energy and the triplet exciton energy of the first compound 342a.

The exciton energy generated at the first compound 342a of delayed fluorescent material in the EML1 342 is transferred efficiently to the second compound 344a of fluorescent material in the EML2 344 so that the EML 340 can realize hyper-fluorescence. In this case, ultimate light emission is occurred in the EML2 344 including the second compound 344a of fluorescent material. Accordingly, the internal quantum efficiency of the OLED D2 can be improved and the color purity of the OLED D2 can be improved caused by the second compound 344a having narrow FWMH.

The EML1 342 and the EML2 344 includes the third compound 342b and the fourth compound 344b, respectively. The third compound 342b can be identical to or different from the fourth compound 344b. For example, each of the third compound 342b and the fourth compound 344b can independently include, but is not limited to, the third compound 340c (FIG. 3) as described in the above embodiment. As an example, each of the third compound 342b and the fourth compound 344b can include, but is not limited to, the organic compound having the structure of Chemical Formulae 11 to 14.

The HOMO energy levels, the LUMO energy levels, excited singlet energy levels and the excited triplet energy levels of the first compound 342a, the second compound 344a, the third compound 342b and the fourth compound 344b can be identical to those of corresponding material with referring to FIG. 3.

For example, each of the excited singlet energy level of the third compound 342b and the excited singlet energy level of the fourth compound 344b can be higher than the excited singlet energy level of the first compound 342a, respectively. Alternatively, each of the excited triplet energy level of the third compound 342b and the excited triplet energy level of the fourth compound 344b can be higher than the excited triplet energy level of the first compound 342a, respectively. For example, the excited triplet energy level of the third compound 342b and the fourth compound 344b can be higher than the excited triplet energy level of the first compound 342a by at least about 0.2 eV or more, for example, about 0.3 eV or more or about 0.5 eV or more.

Also, the excited singlet energy level of the fourth compound 344b of the second host can be higher than the excited singlet energy level of the second compound 344a of fluorescent material. Alternatively, the excited triplet energy level of the fourth compound 344b can be higher than the excited triplet energy level of the second compound 344a. In this case, the singlet exciton energy generated at the fourth compound 344b can be transferred to the singlet exciton of the second compound 344a.

In addition, exciton energy generated at the first compound 342a transformed to the ICT complex state by RISC in the EML1 342 should be transferred efficiently to the second compound 344a in the EML2 344. In order to realize such an organic light emitting diode, the excited singlet energy level of the first compound 342a of delayed fluorescent material in the EML1 342 is higher than the excited singlet energy level of the second compound 344a of fluorescent material in the EML2 344. Alternatively, the excited triplet energy level of the first compound 342a can be higher than the excited triplet energy level of the second compound 344a.

The contents of the third compound 342b and the fourth compound 344b in each of the EML1 342 and the EML2 344, can be larger than the contents of the first compound 342a and the contents of the second compound 344a in the same emitting material layer, respectively. In addition, the contents of the first compound 342a in the EML1 342 can be larger than the contents of the second compound 344a in the EML2 344. In this case, sufficient energy can be transferred to the second compound 344a in the EML2 344 from the first compound 342a in the EML1 342.

For example, the contents of the first compound 342a in the EML1 342 can be, but is not limited to, about 1 wt % to about 50 wt %, for example, about 10 wt % to about 40 wt % or about 20 wt % to about 40 wt %. The contents of the second compound 344a in the EML2 344 can be, but is not limited to, about 1 wt % to about 10 wt %, for example, about 1 wt % to about 5 wt %.

In one example embodiment, when the EML2 344 is disposed adjacently to the HBL 350, the fourth compound 344b in the EML2 344 can be identical to the material in the HBL 350. In this case, the EML2 344 can have both emitting function and hole blocking function. The EML2 344 acts as a buffer layer for blocking holes. Alternatively, the HBL 350 can be omitted and the EML2 344 can be used as an emitting material layer and a hole blocking layer.

In another example embodiment, when the EML2 344 is disposed adjacently to the EBL 330, the fourth compound 344b in the EML2 344 can be identical to the material in the EBL 330. In this case, the EML2 344 can have both emitting function and electron blocking function. The EML2 344 acts as a buffer layer for blocking electrons. Alternatively, the EBL 330 can be omitted and the EML2 344 can be used as an emitting material layer and an electron blocking layer.

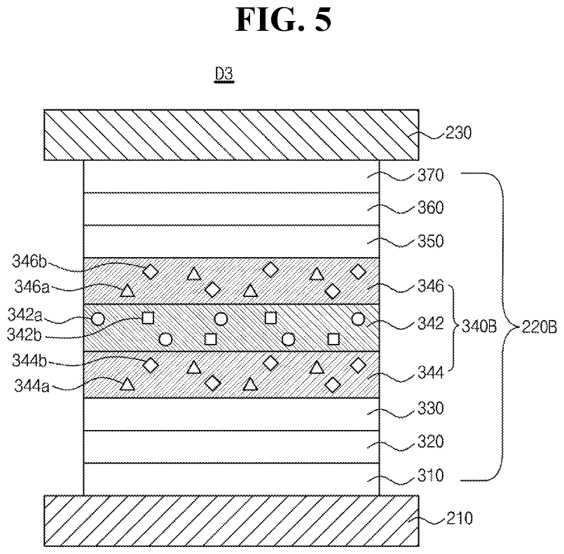

The emitting material layer can have three layers. FIG. 5 illustrates a schematic cross-sectional view of an organic light emitting diode in accordance with another example embodiment of the present disclosure. As illustrated in FIG. 5, the OLED D3 in accordance with another example embodiment includes a first electrode 210, a second electrode 230 facing the first electrode 210 and an emissive layer 220B disposed between the first and second electrodes 210 and 230. The organic light emitting display device 100 (FIG. 2) can include a red pixel region, a green pixel region and a blue pixel region and the OLED D3 can be located at the green pixel region.

The emissive layer 220B includes an emitting material layer (EML) 340B with a three-layered structure. The emissive layer 220B can include at least one of the HTL 320 disposed between the first electrode 210 and the EML 340B and the ETL 360 disposed between the EML 340B and the second electrode 230. The emissive layer 220B can further include at least one of the HIL 310 disposed between the first electrode 210 and the HTL 320 and the EIL 370 disposed between the ETL 360 and the second electrode 230. Alternatively, the emissive layer 220B can further include the EBL 330 disposed between the HTL 320 and the EML 340B and/or the HBL 350 disposed between the EML 340B and the ETL 360. The configurations of the first electrode 210, the second electrode 230 and the emissive layer 220B except the EML 340B can be identical to corresponding elements in the above embodiment.

The EML 340B includes a first EML (EML1, middle EML, first layer) 342 disposed between the EBL 330 and the HBL 350, a second EML (EML2, lower EML, second layer) 344 disposed between the EBL 330 and the EML1 342 and a third EML (EML3, upper EML, third layer) 346 disposed between the EML1 342 and the HBL 350.

The EML1 342 includes a first compound (first dopant) 342a of delayed fluorescent material and each of the EML2 344 and the EML3 346 includes a second compound (second dopant) 344a and a fifth compound 346a (third dopant), respectively. Each of the EML1 342, the EML2 344 and the EML3 346 can further include a third compound 342b of a first host, a fourth compound 344b of a second host and a sixth compound 346b of a third host, respectively.

The singlet exciton energy and the triplet exciton energy generated at the first compound 342a with delayed fluorescent properties in the EML1 342 are transferred to the second compound 344a in the EML2 344 and the fifth compound 346a in the EML3 disposed adjacently to the EML1 342 by FRET mechanism, and the ultimate light emission is occurred at the second compound 344a and the fifth compound 346a.

The triplet exciton energy of the first compound 342a in the EML1 342 is converted upwardly its singlet exciton energy by RISC. The excited singlet exciton energy level of the first compound 342a of delayed fluorescent material is higher than each of the excited singlet energy levels of the second compound 344a and the fifth compound 346a of fluorescent material in each of the EML2 344 and the EML3 346. The singlet exciton energy of the first compound 342a in the EML1 342 is transferred to each of the excited singlet energy level of each of the second compound 344a in the EML2 344 and the fifth compound 346a in the EML3 346 by FRET.

Both the second compound 344a in the EML2 344 and the fifth compound 346a in the EML3 346 can emit light with utilizing both the singlet exciton energy and the triplet exciton energy of the first compound 342a. The second compound 344a and the fifth compound 346a has narrow FWHM (e.g., about 35 nm or less) compared to the first compound 342a. The luminous efficiency as well as the color purity of the OLED D3 can be improved owing to narrow FWHM. Substantial light emission is occurred in the EML2 344 including the second compound 344a and the EML3 346 including the fifth compound 346a.

The first compound 342a of delayed fluorescent material can include the organic compound having the structure of Chemical Formulae 1 to 6 and each of the second compound 344a and the fifth compound 346a of fluorescent material can independently include the boron-based organic compound having the structure of Chemical Formulae 7 to 10. The third compound 342b, the fourth compound 344b and the sixth compound 346b can be identical to or different from each other. For example, each of the third compound 342b, the fourth compound 344b and the sixth compound 346b can independently include, but is not limited to, the third compound 340c (FIG. 3) as described in the above embodiment. As an example, each of the third compound 342b, the fourth compound 344b and the sixth compound can include, but is not limited to, the organic compound having the structure of Chemical Formulae 11 to 14.

The HOMO energy levels, the LUMO energy levels, excited singlet energy levels and the excited triplet energy levels of the first compound 342a, the second compound 344a, the third compound 342b, the fourth compound 344b, the fifth compound 346a and the sixth compound 346b can be identical to those of corresponding material with referring to FIG. 3.

For example, each of the excited singlet energy level of the third compound 342b, the excited singlet energy level of the fourth compound 344b and the excited singlet energy level of the sixth compound 346b can be higher than the excited singlet energy level of the first compound 342a, respectively. Alternatively, each of the excited triplet energy level of the third compound 342b, the excited triplet energy level of the fourth compound 344b and the excited triplet energy level of the sixth compound 346b can be higher than the excited triplet energy level of the first compound 342a, respectively.

In addition, exciton energy generated at the first compound 342a transformed to the ICT complex state by RISC in the EML1 342 should be transferred efficiently to the second compound 344a in the EML2 344 and the fifth compound 346a in the EML3 346. In order to realize such an organic light emitting diode, the excited singlet energy level of the first compound 342a of delayed fluorescent material in the EML1 342 is higher than the excited singlet energy level of the second compound 344a and the fifth compound 346a of fluorescent material in the EML2 344 and EML3 346, respectively. Alternatively, the excited triplet energy level of the first compound 342a can be higher than the excited triplet energy level of the second compound 344a and the fifth compound 346a.

Also, each of the excited singlet energy levels of the fourth compound 344b of the second host and the sixth compound 346b of the third host can be higher than each of the excited singlet energy level of the second compound 344a and the fifth compound 346a of fluorescent material, respectively. Alternatively, each the excited triplet energy levels of the fourth compound 344b and the sixth compound 346b can be higher than each the excited triplet energy levels of the second compound 344a and the fifth compound 346a, respectively.

The contents of the first compound 342a in the EML1 342 can be larger than the contents of the second compound 344a in the EML2 344 and the contents of the fifth compound 346a in the EML3 346. In this case, sufficient energy can be transferred to the second compound 344a in the EML2 344 and the fifth compound 346a in the EML3 346 from the first compound 342a in the EML1 342.

For example, the contents of the first compound 342a in the EML1 342 can be, but is not limited to, about 1 wt % to about 50 wt %, for example, about 10 wt % to about 40 wt % or about 20 wt % to about 40 wt %. The contents of the second compound 344a in the EML2 344 and the contents of the fifth compound 346a in the EML3 346 can be, but is not limited to, about 1 wt % to about 10 wt %, for example, about 1 wt % to about 5 wt %. respectively.

In one example embodiment, when the EML2 344 is disposed adjacently to the EBL 330, the fourth compound 344b in the EML2 344 can be identical to the material in the EBL 330. In this case, the EML2 344 can have both emitting function and electron blocking function. The EML2 344 acts as a buffer layer for blocking electrons. Alternatively, the EBL 330 can be omitted and the EML2 344 can be used as an emitting material layer and an electron blocking layer.

In another example embodiment, when the EML3 346 is disposed adjacently to the HBL 350, the sixth compound 346b in the EML3 346 can be identical to the material in the HBL 350. In this case, the EML3 346 can have both emitting function and hole blocking function. The EML3346 acts as a buffer layer for blocking holes. Alternatively, the HBL 350 can be omitted and the EML3 346 can be used as an emitting material layer and a hole blocking layer.

In another example embodiment, the fourth compound 344b in the EML2 344 can be identical to the material in the EBL 330 and the sixth compound 346b in the EML3 346 can be identical to the material in the HBL 350. In this case, the EML2 344 can have both emitting function and electron blocking function and the EML3 346 can have both emitting function and hole blocking function. The EML2 344 acts as a buffer layer for blocking electrons and the EML3346 acts as a buffer layer for blocking holes. Alternatively, the EBL 330 and the HBL 350 can be omitted and the EML2 344 can be used as an emitting material layer and an electron blocking layer and the EML3 346 can be used as an emitting material layer and a hole blocking layer.

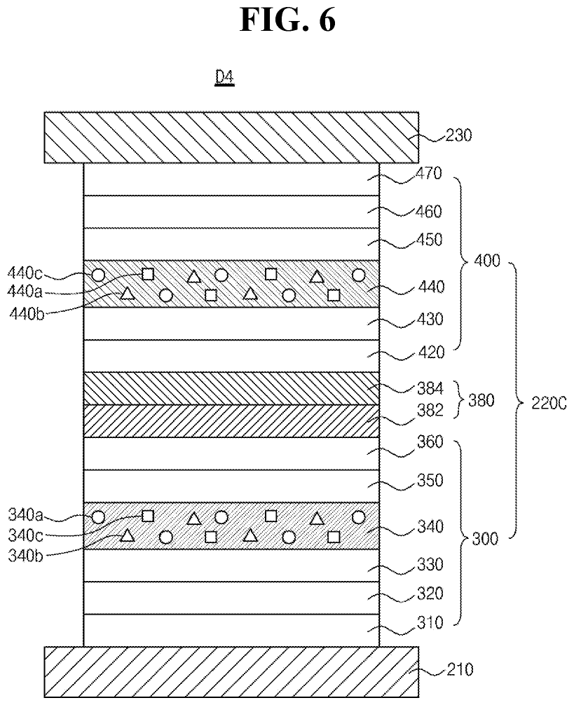

In another example embodiment, the organic light emitting diode can include multiple emitting parts. FIG. 6 illustrates a schematic cross-sectional view of an organic light emitting diode in accordance with another example embodiment of the present disclosure. As illustrated in FIG. 6, the OLED D4 includes a first electrode 210, a second electrode 230 facing to the first electrode 210 and an emissive layer 220C disposed between the first and second electrodes 210 and 230.

The organic light emitting display device 100 (FIG. 2) can include a red pixel region, a green pixel region and a blue pixel region and the OLED D4 can be located at the green pixel region. The first electrode 210 can be an anode and the second electrode can be a cathode.

The emissive layer 220C includes a first emitting part 300 including a first emitting material layer 340, and a second emitting part 400 including a second emitting material layer 440. The emissive layer 220C can further include a charge generation layer (CGL) 380 disposed between the first and second emitting parts 300 and 400. The first emitting part 300, the CGL 380 and the second emitting part 400 are laminated sequentially on the first electrode 210. The first emitting part 300 is disposed between the first electrode 210 and the CGL 380 and the second emitting part 400 is disposed between the CGL 380 and the second electrode 230.

The first emitting part 300 includes the first EML (EML1, lower EML) 340. The first emitting part 300 can include at least one of a hole injection layer (HIL) 310 disposed between the first electrode 210 and the EML1 340, a first hole transport layer (HTL1) 320 disposed between the HIL 310 and the EML1 340 and a first electron transport layer (ETL1) 360 disposed between the EML1 340 and the CGL 380. Alternatively, the first emitting part 300 can further include at least one of a first electron blocking layer (EBL1) 330 disposed between the HTL1 320 and the EML1 340 and a first hole blocking layer (HBL1) 350 disposed between the EML1 340 and the ETL1 360.

The second emitting part 400 includes a second EML (EML2, upper EML) 440. The second emitting part 400 can include at least one of a second hole transport layer (HTL2) 420 disposed between the CGL 380 and the EML2 440, a second electron transport layer (ETL2) 460 disposed between the EML2 440 and the second electrode 230 and an electron injection layer (EIL) 470 disposed between the ETL2 460 and the second electrode 230. Alternatively, the second emitting part 400 can further include at least one of a second electron blocking layer (EBL2) 430 disposed between the HTL2 420 and the EML2 440 and a second hole blocking layer (HBL2) 450 disposed between the EML2 440 and the ETL2 460.

The materials in the HIL 310, HTL1 and HTL2 320 and 420, EBL1 and EBL2 330 and 430, HBL1 and HBL2 350 and 450, ETL1 and ETL2 360 and 460 and EIL 470 can be identical to corresponding materials with referring to FIGS. 3 to 5.

The CGL 380 is disposed between the first emitting part 300 and the second emitting part 400. The first and second emitting parts 300 and 400 are connected by the CGL 380. The CGL 380 can be a PN-junction CGL including an N-type CGL 382 and a P-type CGL 384.

The N-CGL 382 is disposed between the ETL1 360 and the HTL2 420 and the P-CGL 384 is disposed between the N-CGL 382 and the HTL2 420. The N-CGL 382 provides electrons into the EML1 340 of the first emitting part 300 and the P-CGL 384 provides holes into the EML2 440 of the second emitting part 400.

As an example, the N-CGL 382 can include electron transporting material doped with alkali metal (e.g., Li, N, K, Rb and/or Cs) and/or alkaline earth metal (e.g., Mg, Ca, Sr, Ba and/or Ra). The contents of the alkali metal and/or the alkaline earth metal in the N-CGL 382 can be about 1 wt % to about 10 wt %. The P-CGL 384 can include hole transporting material doped with hole injection material (e.g., HAT-CN, F4-TCNQ and/or F6-TCNNQ). The contents of the hole injecting material in the P-CGL 384 can be about 2 wt % to about 15 wt %.

Both the EML1 340 and the EML2 440 can be a green emitting material layer. For example, the EML1 340 can include a first compound 340a of delayed fluorescent material having the structure of Chemical Formulae 1 to 6, a second compound 340b of fluorescent material having the structure of Chemical Formulae 7 to 10, and optionally, a third compound 340c of host.

the EML2 440 can include a first compound 440a of delayed fluorescent material having the structure of Chemical Formulae 1 to 6, a second compound 440b of fluorescent material having the structure of Chemical Formulae 7 to 10, and optionally, a third compound 440c of host.

Each of the first compound 340a, the second compound 340b and the third compound 340c in the EML1 340 can be independently identical to or different from each of the first compound 440a, the second compound 440b and the third compound 440c in the EML2 440, respectively. The materials in the EML1 340 and EML2 440 can be identical to corresponding materials with referring to FIG. 3.

Alternatively, the EML2 440 can include other materials different from at least one of the first compound 340a, the second compound 340b and the third compound 340c in the EML1 340 so that the EML2 440 can emit color different from the EML1 340 or have luminous efficiency different from the EML1 340.

In FIG. 6, each of the EML1 340 and the EML2 440 has a single-layered structure. Alternatively, each of the EML1 340 and the EML2 440 can have a two-layered structure (FIG. 4) or a three-layered structure (FIG. 5).

Singlet exciton energy generated at the first compound 340a or 440a of delayed fluorescent material is transferred to the second compound 340b or 440b of fluorescent material where the ultimate light emission is occurred. The luminous efficiency and color purity of the OLED D4 can be improved. At least one of the EML1 340 and the EML2 440 uses the first compound 340a or 440a having the structure of Chemical Formulae 1 to 6 and the second compound 340b or 440b having the structure of Chemical Formulae 7 to 10 so that the luminous efficiency and the color purity can be further improved. In addition, the OLED D4 has a double stack structure of two green emitting material layers so that the color of the OLED D4 can be improved or the luminous efficiency of the OLED D4 can be optimized.

In the above embodiments, an organic light emitting diode and an organic light emitting device emitting specific color light is described. In another example embodiment, an organic light emitting display device can implement full-color including white color. FIG. 7 illustrates a schematic cross-sectional view of an organic light emitting display device in accordance with another example embodiment of the present disclosure.

As illustrated in FIG. 7, the organic light emitting display device 500 includes a first substrate 510 that has a first pixel region P1, a second pixel region P2 and a third pixel region P3, a second substrate 512 facing the first substrate 510, a thin film transistor Tr on the first substrate 510, an OLED D disposed between the first and second substrates 510 and 512 emitting white (W) light and a color filter layer 590 disposed between the OLED D and the second substrate 512. For example, each of the first to third pixel regions P1, P2 and P3 can be a red pixel region, a green pixel region and a blue pixel region, respectively. Alternatively, the first substrate 510 can further include a fourth pixel region of a white pixel region.

Each of the first and second substrates 510 and 512 can include, but is not limited to, glass, flexible material and/or polymer plastics. For example, each of the first and substrate 510 and the second substrate 512 can be made of PI, PES, PEN, PET, PC and/or combinations thereof. The second substrate 512 can be omitted. The first substrate 510, on which a thin film transistor Tr and the OLED D are arranged, forms an array substrate.

The thin film transistor Tr is disposed on the first substrate 510. Alternatively, a buffer layer is disposed on the first substrate 510 and the thin film transistor Tr can be disposed on the buffer layer. As illustrated in FIG. 2, the thin film transistor includes a semiconductor layer, a gate electrode, a source electrode and a drain electrode and functions as a driving element.

A passivation layer 570 is disposed on the thin film transistor Tr. The passivation layer 570 has a flat top surface and a drain contact hole 572 that exposes a drain electrode.

The OLED D is disposed on the passivation layer 570 and corresponding to the color filter layer 590. The OLED D includes a first electrode 610 connected to a drain electrode of the thin film transistor, an emissive layer 620 and a second electrode 630 disposed sequentially on the first electrode 610. The OLED D emits white color light in each of the first to third pixel regions P1, P2 and P3.

The first electrode 610 is disposed separately for each of the first to third pixel regions P1, P2 and P3 and the second electrode 630 can be disposed integrally corresponding to the first to third pixel regions P1, P2 and P3. The first electrode 610 can be one of an anode and a cathode and the second electrode 630 can be the other of an anode and a cathode. In one example embodiment, the first electrode 610 can be a reflective electrode and the second electrode 630 can be a transmissive (semi-transmissive) electrode. Alternatively, the first electrode 610 can be a transmissive (semi-transmissive) electrode and the second electrode 620 can be a reflective electrode.

For example, the first electrode 610 can be an anode and can include a conductive material having relatively high work function value, for example, a conductive oxide layer of transparent conductive oxide (TCO). For example, the first electrode 610 can include, but is not limited to, ITO, IZO, ITZO, SnO, ZnO, ICO, AZO, and/or the like. Alternatively, a reflective electrode or a reflective layer can be disposed under the first electrode 610. For example, the reflective electrode or the reflective layer can include, but is not limited to, Ag or APC alloy.

The second electrode 630 can be a cathode and can include conductive material with a relatively low work function value compared to the first electrode 610, for example, a metal layer of low resistant metal. For example, the second electrode 630 can include, but is not limited to, Al, Mg, Ca, Ag, alloy thereof, and/or combinations thereof such as Al-Mg. Since the light emitted from the emissive layer 620 is incident to the color filter layer 590 through the second electrode 630 in the organic light emitting display device 500, the second electrode 630 can have a thin thickness so that the light can be transmitted.

An emissive layer 620 that can include multiple emitting parts each of which can emit different color light is disposed on the first electrode 610. Each of the emitting parts can have a single-layered structure of an emitting material layer (EML). Alternatively, each of the emitting parts can further include at least one of a hole injection layer (HIL), a hole transport layer (HTL), an electron blocking layer (EBL), a hole blocking layer (HBL), an electron transport layer (ETL) and an electron injection layer (EIL). In addition, the emissive layer 620 can further include a charge generation layer (CGL) disposed between the emitting parts.

A bank layer 574 is disposed on the passivation layer 570 in order to cover edges of the first electrode 610. The bank layer 574 exposes or does not cover a center of the first electrode 610 corresponding to each of the first to third pixel regions P1, P2 and P3 to prevent current leakage in the edge of the first electrode 610. The bank layer 574 can be omitted.

Since the OLED D emits white color light in each of the first to third pixel regions P1, P2 and P3, the emissive layer 620 can be disposed as a common layer without separating in the first to third pixel regions P1, P2 and P3.

In addition, an encapsulation film 580 can be disposed on the second electrode 630 in order to prevent or reduce outer moisture from penetrating into the OLED D. In addition, a polarizing plate can be attached under the first substrate 510 or on the second substrate 512 to reduce reflection of external light.

The color filter layer 590 is disposed on the OLED D or the encapsulation film 580. As an example, the color filter layer 590 can include a first color filter layer 592, a second color filter layer 594 and a third color filter layer 596 each of which is disposed correspondingly to the first pixel region P1, the second pixel region P2 and the third pixel region P3, respectively. For example, the first color filter layer 592 can be a red color filter layer, the second color filter layer 594 can be a green color filter layer and the third color filter layer 596 can be a blue color filter layer.

The first color filter layer 592 can include at least one of a red dye and a red pigment, the second color filter layer 594 can include at least one of a green dye and a green pigment and the third color filter layer 596 can include at least one of a blue dye and a blue pigment. Although not shown in FIG. 7, the color filter layer 590 can be attached to the OLED D through an adhesive layer. Alternatively, the color filter layer 590 can be disposed directly on the OLED D.

In FIG. 7, the light emitted from the OLED D is transmitted through the second electrode 630 and the color filter layer 590 is disposed on the OLED D. In this case, the organic light emitting display device 500 can be a top-emission type. Alternatively, when the organic light emitting display device 500 is a bottom-emission type, the light emitted from the OLED D is transmitted through the first electrode 610 and the color filter layer 590 can be disposed between the OLED D and the first substrate 510.

In addition, a color conversion layer may be formed or disposed between the OLED D and the color filter layer 590. The color conversion layer can include a red color conversion layer, a green color conversion layer and a blue color conversion layer each of which is disposed correspondingly to each of the first to third pixel regions P1, P2 and P3, respectively, so as to convert the white (W) color light to each of a red, green and blue color lights, respectively. For example, color conversion layer can include quantum dots. The color conversion layer can improve the color purity of the organic light emitting display device 500. Alternatively, the organic light emitting display device 500 can comprise the color conversion layer instead of the color filter layer 590.

As described above, the white (W) color light emitted from the OLED D is transmitted through the red color filter layer 592, the second color filter layer 594 and the third color filter layer 596 each of which is disposed correspondingly to the first to third pixel regions P1, P2 and P3, respectively, so that red, green and blue color lights are displayed in each of the first to third pixel regions P1, P2 and P3, respectively.

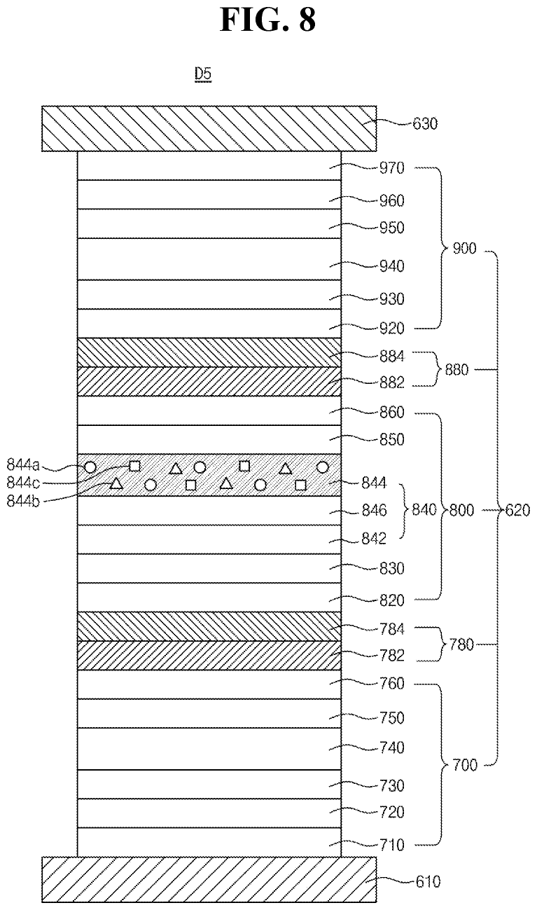

An OLED that can be applied into the organic light emitting display device will be described in more detail. FIG. 8 illustrates a schematic cross-sectional view of an organic light emitting diode having a tandem structure of three emitting parts.

As illustrated in FIG. 8, the OLED D5 includes first and second electrodes 610 and 630 facing each other and an emissive layer 620 disposed between the first and second electrodes 610 and 630. The emissive layer 620 includes a first emitting part 700 disposed between the first and second electrodes 610 and 630, a second emitting part 800 disposed between the first emitting part 700 and the second electrode 630, a third emitting part 900 disposed between the second emitting part 800 and the second electrode 630, a first charge generation layer (CGL1) 780 disposed between the first and second emitting parts 700 and 800, and a second charge generation layer (CGL2) 880 disposed between the second and third emitting parts 800 and 900.

The first emitting part 700 includes a first EML (EML1) 740. The first emitting part 700 can further include at least one of a hole injection layer (HIL) 710 disposed between the first electrode 610 and the EML1 740, a first hole transport layer (HTL1) 720 disposed between the HIL 710 and the EML1 740, a first electron transport layer (ETL1) 760 disposed between the EML1 740 and the CGL1 780. Alternatively, the first emitting part 700 can further include a first electron blocking layer (EBL1) 730 disposed between the HTL1 720 and the EML1 740 and/or a first hole blocking layer (HBL1) 750 disposed between the EML1 740 and the ETL1 760.

The second emitting part 800 includes a second EML (EML2) 840. The second emitting part 800 can further include at least one of a second hole transport layer (HTL2) 820 disposed between the CGL1 780 and the EML2 840 and a second electron transport layer (ETL2) 860 disposed between the EML2 840 and the CGL2 880. Alternatively, the second emitting part 800 can further include a second electron blocking layer (EBL2) 830 disposed between the HTL2 820 and the EML2 840 and/or a second hole blocking layer (HBL2) 850 disposed between the EML2 840 and the ETL2 860.

The third emitting part 900 includes a third EML (EML3) 940. The third emitting part 900 can further include at least one of a third hole transport layer (HTL3) 920 disposed between the CGL2 880 and the EML3 940, a third electron transport layer (ETL3) 960 disposed between the second electrode 630 and the EML3 940 and an electron injection layer (EIL) 970 disposed between the second electrode 630 and the ETL3 960. Alternatively, the third emitting part 900 can further comprise a third electron blocking layer (EBL3) 930 disposed between the HTL3 920 and the EML3 940 and/or a third hole blocking layer (HBL3) 950 disposed between the EML3 940 and the ETL3 960.

The CGL1 780 is disposed between the first emitting part 700 and the second emitting part 800 and the CGL2 880 is disposed between the second emitting part 800 and the third emitting part 900. The CGL1 780 includes a first N-type charge generation layer (N-CGL1) 782 disposed between the ETL1 760 and the HTL2 820 and a first P-type charge generation layer (P-CGL1) 784 disposed between the N-CGL1 782 and the HTL2 820. The CGL2 880 includes a second N-type charge generation layer (N-CGL2) 882 disposed between the ETL2 860 and the HTL3 920 and a second P-type charge generation layer (P-CGL2) 884 disposed between the N-CGL2 882 and the HTL3 920.

Each of the N-CGL1 782 and the N-CGL2 882 provides electrons to each of the EML1 740 and the EML2 840, respectively, and each of the P-CGL1 784 and the P-CGL2 884 provides holes to each of the EML2 840 and the EML3 940, respectively.

The materials in the HIL 710, the HTL1 to HTL3 720, 820 and 920, the EBL1 to EBL3 730, 830 and 930, the HBL1 to HBL3 750, 850 and 950, the ETL1 to ETL3 760, 860 and 960, the EIL 970 and the CGL1 and CGL2 780 and 880 can be identical to corresponding materials with referring to FIGS. 3 to 6.

At least one of the EML1 740, the EML2 840 and the EML3 940 can include a first compound, a second compound, and optionally, a third compound to emit green color light. As an example, at least one of the EML1 740, the EML2 840 and the EML3 940 can emit blue color light and others of the EML1 740, the EML2 840 and the EML3 940 can emit red or green color light so that the OLED D5 can implement white emission. Hereinafter, the OLED D5 where the EML1 740 and/or the EML3 940 emit blue color light and the EML2 840 emits red or green color light will be described in detail.

Each of the EML1 740 and the EML3 940 can be independently a blue emitting material layer. In this case, each of the EML1 740 and the EML3 940 can be independently a blue emitting material layer, a sky-blue emitting material layer or a deep-blue emitting material layer. Each of the EML1 740 and the EML3 940 can independently include a blue host and a blue emitter (blue dopant). The blue host can include at least one of a P-type blue host and an N-type blue host.

For example, the blue host can include, but is not limited to, mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3 -(diphenylpho sphoryl)-9H-carbazole (mCPP01) 3 ,5-Di(9H-carbazol-9-yl)biphenyl (Ph-mCP), TSPO1, 9-(3′-(9H-carbazol-9-yl)-[1,1′-biphenyl]-3-yl)-9H-pyrido [2,3 -I)] indole (CzBPCb), B is(2-methylphenyl)diphenylsilane (UGH-1), 1,4-B is(triphenylsilyl)benzene (UGH-2), 1,3-B is(triphenylsilyl)benzene (UGH-3), 9,9-Spirobifluoren-2-yl-diphenyl-phosphine oxide (SPPO1), 9,9′-(5-(Triphenylsilyl)-1,3-phenylene)bis(9H-carbazole) (SimCP) and/or combinations thereof.

The blue emitter can include at least one of blue phosphorescent material, blue fluorescent material and blue delayed fluorescent material. As an example, the blue emitter can include, but is not limited to, perylene, 4,4′-Bis[4-(di-p-tolylamino)styryl]biphenyl (DPAVBi), 4-(Di-p-tolylamino)-4-4′-[(di-p-tolylamino)styryl] stilbene (DPAVB), 4,4′-Bis [4-(diphenylamino)styryl]biphenyl (BDAVBi), 2,7-B is (4-diphenylamino)s tyryl)-9,9- spirofluorene (spiro-DPVBi), [1,4-bis[2[4-[N,N-di(p-tolyl)amino]phenyl]vinyl]benzene (DSB), 1-4-di- [4-(N,N-diphenyl)amino] styryl-benzene (DSA), 2,5 ,8,11-Tetra-tert-butylperylene (TB Pe), B is (2-hydroxylphenyl)-pyridine)beryllium (B epp2), 9-(9-Phenylcarbazol-3 -yl)-10-(n aphthalen-1 -yl)anthracene (PCAN), mer-Tris(1-phenyl-3-methylimidazolin-2- ylidene-C,C(2)' iridium(III) (mer-Ir(pmi)3), fac-Tris(1,3-diphenyl-benzimidazolin-2-ylidene-C,C(2)' iridium(III) (fac-Ir(dpbic)3), B is (3 ,4,5-trifluoro-2-(2-pyridyl)pheny 1-(2-c arboxypyridyl)iridium(III) (Ir(tfpd)2pic), tris(2-(4,6-difluorophenyl)pyridine))iridium(III) (Ir(Fppy)3), Bis[2-(4,6-difluorophenyl)pyridinato-C 2 ,N](picolinato)iridium(III) (Flrpic) and/or combinations thereof.

Each of the blue host and the blue emitter in the EML1 740 can be independently identical to or different from each of the blue host and the blue emitter in the EML3 940. For example, the EML3 940 can include materials different from at least one of the blue host and the blue emitter in the EML1 740 so that the EML3 940 can emit different color light from the EML1 740 or can have luminous efficiency different from the EML1 740.

When each of the EML1 740 and the EML3 940 includes one or more blue hosts, the contents of the blue host in each of the EML1 740 and the EML3 940 can be independently about 50 wt % to about 99 wt %, for example, about 80 wt % to about 95 wt %, respectively, and the contents of the blue emitter in each of the EML1 740 and the EML3 940 can be independently about 1 wt % to about 50 wt %, for example, about 5 wt % to about 20 wt %, but is not limited thereto. When each of the EML1 740 and the EML3 940 includes both the P-type blue host and the N-type blue host, the P-type blue host and the N-type blue host in each of the EML1 740 and the EML3 940 can be independently admixed with weight ratio of about 4:1 to about 1:4, for example, about 3:1 to about 1:3, respectively, but is not limited thereto.

The EML2 840 can include a first layer 842 disposed between the EBL2 830 and the HBL2 850, a second layer 844 disposed between the first layer 842 and the HBL2 850, and optionally, a third layer 846 disposed between the first layer 842 and the second layer 844. For example, one of the first layer 842 and the second layer 844 can emit red color and the other of the first layer 842 and the second layer 844 can emit green color. Hereinafter, the EML2 840 where the first layer 842 emits a red color and the second layer 844 emits a green color will be described in detail.

The first layer 842 includes a red host and a red emitter (red dopant). The red host can include at least one of a P-type red host and an N-type red host. For example, the red host can include, but is not limited to, mCP-CN, CBP, mCBP, mCP, DPEPO, PPT, TmPyPB, PYD-2Cz, DCzDB T, DCzTPA, pCzB -2CN, mCzB -2CN, TSP01, CCP, 4-(3-(triphenylen-2-yl)dibenzo [b,d]thiophene, 9-(4-(9H-carb azol-9 -yl)phenyl)-9H-3 ,9 ‘ - bicarbazole, 9-(3 -(9H-carbazol-9-yl)phenyl)-9H-3 ,9 ’ -bicarbazole, 9-(6-(9H-carbazol-9-yl)pyridin-3 -yl)-9H-3 ,9 ′-bicarbazole, BCzPh, TCP, TCTA, CDBP, DMFL-CBP, Spiro-CBP, TCz1 and combinations thereof.

The red emitter can include at least one of red phosphorescent material, red fluorescent material and red delayed fluorescent material. For example, the red emitter can include, Bis[2-(4,6-dimethyl)phenylquinoline)] (2,2,6,6-tetramethylheptane-3,5-dionate)iridium(III), Bis[2-(4-n-hexylphenyl)quinoline](acetylacetonate)iridium(III) (Hex-Ir(phq)₂(acac)), Tris[2- (4-n-hexylphenyl)quinoline]iridium(III) (Hex-Ir(phq)3), Tris [2-phenyl-4-methylquinoline]iridium(III) (Ir(Mphq)₃), Bis(2-phenylquinoline)(2,2,6,6-tetramethylheptene-3 ,5-dionate)iridium(III) (Ir(dpm)PQ₂), Bis(phenylisoquinoline)(2,2,6,6-tetramethylheptene-3,5-dionate)iridium(III) (Jr(dpm)(piq)₂), Bis(1 -phenylisoquin o tine Kacety laceton ate (Jr(piq)₂(acac)), Bis[(4-n-hexylphenyl)is oquinoline] (acetylac etonate)iridium(III) (Hex-Ir(piq)₂(acac)), Tris[2-(4-n-hexylphenyl)quinoline]iridium(III) (Hex-Ir(piq)3), Tris(2-(3-methylphenyl)-7-methyl-quinolato)iridium (Ir(dmpq)3), Bis [2-(2-methylphenyl)-7 -methyl-quinoline](acetylacetonate)iridium(III) (Ir(dmpq)2(acac)), Bi [2-(3,5 -dimethylphenyl)-4-methyl-quinoline](acetylacetonate)iridium(III) (Ir(mphmq)₂(acac)), Tris(dibenzoylmethane)mono(1,10-plaenanthroline)europium(III) (Eu(dbm)₃(phen)) and/or combinations thereof.

For example, the contents of the red host in the first layer 842 can be about 50 wt % to about 99 wt %, for example, about 80 wt % to about 95 wt %, and the contents of the red emitter in the first layer 842 can be about 1 wt % to about 50 wt %, for example, about 5 wt % to about 20 wt %, but is not limited thereto. When the first layer 842 includes both the P-type red host and the N-type red host, the P-type red host and the N-type red host in the first layer 842 can be independently admixed with weight ratio of about 4:1 to about 1:4, for example, about 3:1 to about 1:3, respectively, but is not limited thereto.

The second layer 844 includes a first compound 844a of delayed fluorescent material having the structure of Chemical Formulae 1 to 6, a second compound 844b of fluorescent material having the structure of Chemical Formulae 7 to 10, and optionally, a third compound 844c of host having the structure of Chemical Formulae 11 to 14.

The HOMO energy levels, the LUMO energy levels, the excited singlet energy levels and the excited triplet energy levels of the first compound 844a, the second compound 844b and the third compound 844c as well as the contents of those compounds in the second layer 844 can be identical to corresponding energy levels and contents with referring to FIG. 3.

The third layer 846 can be a yellow green EML. The third layer 846 can include a yellow green host and a yellow green emitter (yellow green dopant). The yellow green host can include at least one of a P-type yellow green host and an N-type yellow green host. As an example, the yellow green host can be identical to at least one of the green host and the red host.

The yellow green emitter can include at least one of yellow green phosphorescent material, yellow green fluorescent material and yellow green delayed fluorescent material.

For example, the yellow green emitter can include, but is not limited to, 5,6,11,12-Tetraphenylnaphthalene (Rubrene), 2,8-Di-tert-butyl-5,11-bis(4-tert-butylphenyl)-6,12-diphenyltetracene (TBRb), B is (2-phenylbenzothiazolato)(acetylacetonate)iridium(III) (Ir(BT)₂(acac)), B is(2-(9,9-diethytl-fluoren-2-yl)-1-phenyl-1H-benzo[d]imdiazolato)(acetylacetonate)iridium(III) (Ir(fbi)₂(acac)), Bis(2-phenylpyridine)(3-(pyridine-2-yl)-2H-chromen-2-onate)iridium(III) (fac-Ir(ppy)₂Pc), Bis(2-(2,4-difluorophenyl)quinoline)(picolinate)iridium(III) (FPQlrpic), Bis(4-phenylthieno [3,2-c]pyridinato-N,C2′) (acetylacetonate) iridium(III) (PO-01) and/or combinations thereof. The third layer 740C can be omitted.

For example, the contents of the yellow green host in the third layer 846 can be about 50 wt % to about 99 wt %, for example, about 80 wt % to about 95 wt %, and the contents of the yellow green emitter in the third layer 846 can be about 1 wt % to about 50 wt %, for example, about 5 wt % to about 20 wt %, but is not limited thereto. When the third layer 846 includes both the P-type yellow green host and the N-type yellow green host, the P-type yellow green host and the N-type yellow green host in the third layer 846 can be independently admixed with weight ratio of about 4:1 to about 1:4, for example, about 3:1 to about 1:3, respectively, but is not limited thereto.

Alternatively, the third emitting part 900 and the CGL2 880 can be omitted so that the organic light emitting diode can have two emitting parts. In addition, the second layer 884 can have a two-layered structure (FIG. 4) or a three-layered structure (FIG. 5).

The OLED D5 has a tandem structure in which includes the first compound 844a of delayed fluorescent material and the second compound 844b of fluorescent material. Exciton energy can be transferred efficiently to the second compound 844b from the first compound 844a so that the driving voltage of the OLED D5 can be lowered and the luminous efficiency and the color purity of the OLED D5 can be improved. Accordingly, it is possible to implement white light emission with improving the luminous efficiency and luminous lifespan of an organic light emitting diode having multiple emitting parts.

### EXAMPLE 1 (Ex.1): FABRICATION OF OLED

An organic light emitting diode where an emitting material layer includes Compound 1-1 (HOMO: −5.40 eV, LUMO: −2.49 eV, maximum PL wavelength: 520 nm) in Chemical Formula 6 of a first compound and Compound 3-1 (mCBP, HOMO: −6.0 eV, LUMO: −2.4 eV) in Chemical Formula 14 of a third compound was fabricated.

A glass substrate onto which ITO (50 nm) was coated was washed with UV ozone. The substrate was loaded on a evaporation system and transferred to a vacuum chamber for depositing emissive layer. Subsequently, an emissive layer and a cathode were deposited by evaporation from a heating boat under about 10⁻⁷ torr with setting a deposition rate 1 Å/s as the following order:

Anode (ITO, 50 nm); A hole injection layer (HIL, HAT-CN, 7 nm); a hole transport layer (HTL, NPB, 45 nm); an electron blocking layer (EBL, TAPC, 10 nm); an emitting material layer (mCBP (50 wt %), Compound 1-1 (50 wt %), 30 nm); a hole blocking layer (HBL, B3PYMPM, 10 nm); an electron blocking layer (ETL, TPBi, 30 nm); an electron injection layer (EIL, LiF); and cathode (Al).

The structures of materials used in the emissive layer and the CPL are illustrated in the following:

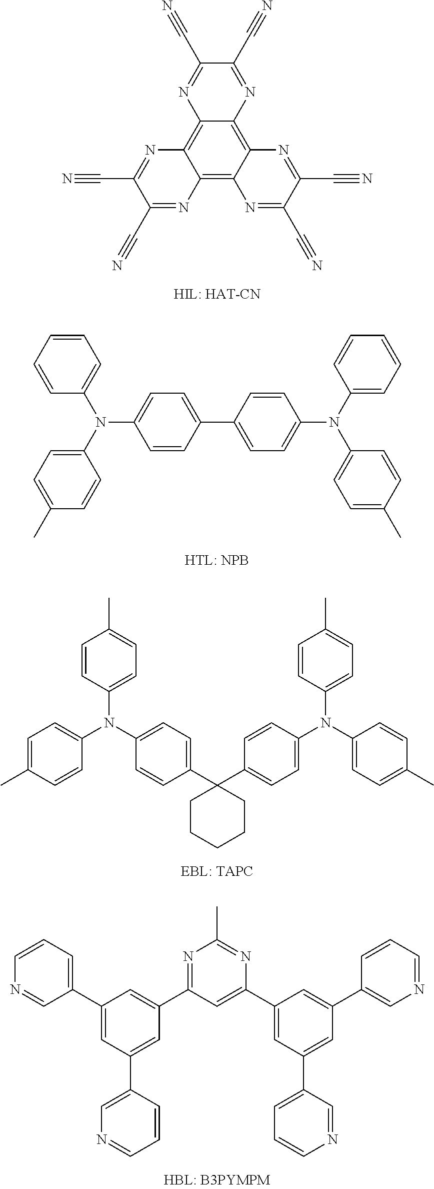

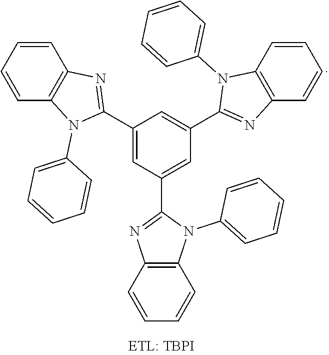 [SMILES: c1ccc(-n2c(-c3cc(-c4nc5ccccc5n4-c4ccccc4)cc(-c4nc5ccccc5n4-c4ccccc4)c3)nc3ccccc32)cc1]

### EXAMPLE 2 (Ex. 2): FABRICATION OF OLED

An OLED was fabricated using the same procedure and the same material as Example 1, except that EML includes mCBP (50 wt %), Compound 1-1 (49.2 wt %) and Compound 2-1-1 (0.8 wt %) in Chemical Formula 8 of a second compound.

### EXAMPLE 3 (EX. 3): FABRICATION OF OLED

An OLED was fabricated using the same procedure and the same material as Example 1, except that Compound 1-2 (HOMO: −5.33 eV, LUMO: −2.47 eV, maximum PL wavelength: 531 nm) in Chemical Formula 6 instead of Compound 1-1 was used as the first compound.

### EXAMPLE 4 (EX. 4): FABRICATION OF OLED

An OLED was fabricated using the same procedure and the same material as Example 3, except that EML includes mCBP (50 wt %), Compound 1-2 (49.2 wt %) and Compound 2-1-1 (0.8 wt %) in Chemical Formula 8 of a second compound.

### EXAMPLE 5 (EX. 5): FABRICATION OF OLED

An OLED was fabricated using the same procedure and the same material as Example 1, except that Compound 1-3 (HOMO: −5.26 eV, LUMO: −2.44 eV, maximum PL wavelength: 536 nm) in Chemical Formula 6 instead of Compound 1-1 was used as the first compound.

### EXAMPLE 6 (Ex. 6): FABRICATION of oled

An OLED was fabricated using the same procedure and the same material as Example 5, except that EML includes mCBP (50 wt %), Compound 1-3 (49.2 wt %) and Compound 2-1-1 (0.8 wt %) in Chemical Formula 8 of a second compound.

### Comparative Example 1 (Ref. 1): Fabrication of OLED

An OLED was fabricated using the same procedure and the same material as Example 1, except that following Compound Ref. 1 (4CzIPN, HOMO: −5.80 eV, LUMO: −3.40 eV, maximum PL wavelength: 544 nm) instead of Compound 1-1 was used as the first compound.

### Comparative Example 2 (Ref. 2): Fabrication of OLED

An OLED was fabricated using the same procedure and the same material as Comparative Example 1, except that EML includes mCBP (50 wt %), Compound Ref. 1 (49.2 wt %) and Compound 2-1-1 (0.8 wt %) in Chemical Formula 8 of a second compound.

### Comparative Example 3 (Ref. 3): Fabrication of OLED

An OLED was fabricated using the same procedure and the same material as Example 1, except that following Compound Ref. 2 (HOMO: −5.32 eV, LUMO: −2.28 eV, maximum PL wavelength: 491 nm) instead of Compound 1-1 was used as the first compound.

### Comparative Example 4 (Ref. 4): Fabrication of OLED

An OLED was fabricated using the same procedure and the same material as Comparative Example 3, except that EML includes mCBP (50 wt %), Compound Ref. 2 (49.2 wt %) and Compound 2-1-1 (0.8 wt %) in Chemical Formula 8 of a second compound.

### Comparative Example 5 (Ref. 5): Fabrication of OLED

An OLED was fabricated using the same procedure and the same material as Example 1, except that following Compound Ref. 3 (HOMO: −5.10 eV, LUMO: −2.49 eV, maximum PL wavelength: 477 nm) instead of Compound 1-1 was used as the first compound.

### Comparative Example 6 (Ref. 6): Fabrication of OLED

An OLED was fabricated using the same procedure and the same material as Comparative Example 5, except that EML includes mCBP (50 wt %), Compound Ref. 3 (49.2 wt %) and Compound 2-1-1 (0.8 wt %) in Chemical Formula 8 of a second compound.

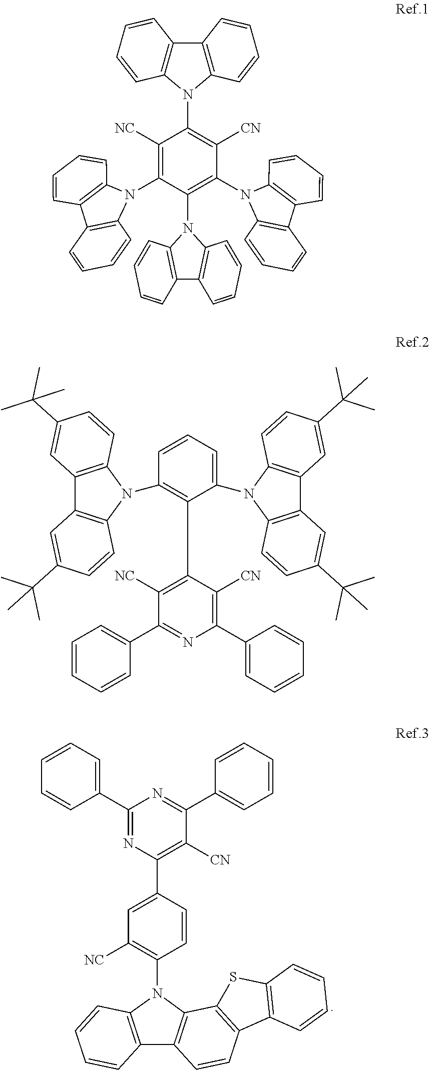 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21 ; CC(C)(C)c1ccc2c(c1)c1cc(C(C)(C)C)ccc1n2-c1cccc(-n2c3ccc(C(C)(C)C)cc3c3cc(C(C)(C)C)ccc32)c1-c1c(C#N)c(-c2ccccc2)nc(-c2ccccc2)c1C#N ; N#Cc1cc(-c2nc(-c3ccccc3)nc(-c3ccccc3)c2C#N)ccc1-n1c2ccccc2c2ccc3c4ccccc4sc3c21]

### Experimental Example 1: Measurement of Luminous Properties of OLEDs

The luminous properties for each of the OLEDs fabricated in Examples 1 to 6 and Comparative Examples 1 to 6 was measured. Each of the OLEDs having 9 mm 2 of emission area connected to an external power source and then luminous properties for all the OLEDs were evaluated using a constant current source (KEITHLEY) and a photometer PR650 at room temperature. In particular, driving voltage (V), current efficiency (cd/A), power efficiency (1 m/W), External quantum efficiency (EQE, %), luminance (cd/m²), color coordinates (CIEx, CIEy), maximum electroluminescence wavelength (λₘₐₓ, nm) and FWHM (nm) were measured at a current density 8.6 mA/cm². The measurement results are indicated in the following Table 1.

TABLE 1
Luminous property of OLED

| | | | | EQE | | | | | |
|---|---|---|---|---|---|---|---|---|---|
| Sample | V | cd/A | lm/W | (%) | cd/m² | CIEx | CIEy | λₘₐₓ | FWHM |
| Ref. 1 | 3.7 | 51.6 | 43.4 | 15.4 | 3252 | 0.395 | 0.573 | 546 | 88 |
| Ref. 2 | 3.7 | 47.1 | 39.9 | 14.1 | 2992 | 0.330 | 0.638 | 532 | 36 |
| Ref. 3 | 3.3 | 34.7 | 31.3 | 10.9 | 2184 | 0.305 | 0.571 | 522 | 87 |
| Ref. 4 | 3.4 | 45.6 | 41.2 | 13.3 | 2971 | 0.276 | 0.617 | 526 | 28 |
| Ref. 5 | 3.8 | 66.5 | 54.9 | 20.3 | 4191 | 0.342 | 0.578 | 528 | 92 |
| Ref. 6 | 4.0 | 55.8 | 43.9 | 15.9 | 3516 | 0.315 | 0.613 | 524 | 57 |
| Ex. 1 | 3.2 | 44.9 | 44.1 | 13.7 | 2827 | 0.303 | 0.587 | 522 | 82 |
| Ex. 2 | 3.2 | 75.2 | 73.4 | 19.4 | 4741 | 0.280 | 0.663 | 528 | 30 |
| Ex. 3 | 3.4 | 59.0 | 55.1 | 17.2 | 3719 | 0.367 | 0.591 | 534 | 83 |
| Ex. 4 | 3.5 | 89.5 | 81.3 | 23.0 | 5638 | 0.317 | 0.648 | 530 | 33 |
| Ex. 5 | 3.3 | 65.1 | 61.3 | 19.0 | 4103 | 0.376 | 0.585 | 538 | 87 |
| Ex. 6 | 3.3 | 99.0 | 95.1 | 25.0 | 6236 | 0.310 | 0.658 | 530 | 32 |

As indicated in Table 1, compared to the OLEDs fabricated in Ref. 1, 3, and 5 where the EML includes only the first compound and the third compound, in the OLEDs fabricated in Ref. 2, 4, and 6 where the EML further includes the second compound, the luminous efficiency was rather lowered or little improved. On the contrary, compared to the OLEDs fabricated in Ex. 1, 3, and 5 wherein the EML includes only the first compound and the third compound, in the OLEDs fabricated in Ex. 2, 4 and 6 where the EML further includes the second compound, the luminous efficiency was improved significantly (cd/A, 1 m/W, EQE and luminance was improved by maximally 67.5%, 66.4%, 41.6% and 67.7%, respectively).

Accordingly, compared to the OLEDs fabricated in Ref. 2, 4 and 6 where the EML includes the first, second, and third compounds, in the OLEDs fabricated in Ex. 2, 4, and 6, the driving voltage was lowered by maximally 21.2%, and cd/A, 1 m/W, EQE and luminance was increased by maximally 117.1%, 138.3%, 88.0% and 109.0%, respectively. In addition, compared to the OLEDs fabricated in Ref. 2, 4 and 6, in the OLEDs fabricated in Ex. 2, 4 and 6, much deeper green light was emitted.

It will be apparent to those skilled in the art that various modifications and variations may be made in the present disclosure without departing from the scope of the disclosure. Thus, it is intended that the present disclosure cover the modifications and variations of the present disclosure provided they come within the scope of the appended claims.

What is claimed is:

1. An organic light emitting diode, including:
a first electrode;
a second electrode facing the first electrode; and
an emissive layer disposed between the first electrode and second electrode, and including at least one emitting material layer,
wherein the at least one emitting material layer includes a first compound and a second compound,
wherein the first compound includes an organic compound having the following structure of Chemical Formula 1, and
wherein the second compound includes an organic compound having the following structure of Chemical Formula 7 or Chemical Formula 9: 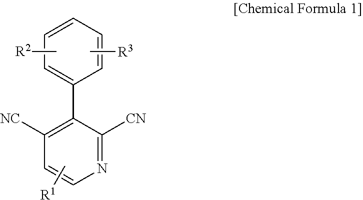
wherein, in the Chemical Formula 1,
R¹ is a hydrogen atom, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group; and
each of R² and R³ is independently a moiety having the following structure of Chemical Formula 2, 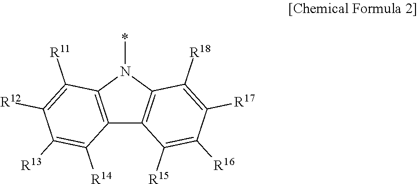
wherein, in the Chemical Formula 2,
each of R¹¹ to R¹⁸ is independently a hydrogen atom, a halogen atom, an unsubstituted or substituted C₁-C₂₀ alkyl group, an unsubstituted or substituted C₁-C₂₀ alkyl silyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group, or
two adjacent groups among R¹¹ to R¹⁸ are linked together to form an unsubstituted or substituted C₆-C₂₀ aryl ring or an unsubstituted or substituted C₃-C₂₀ hetero aryl ring, where at least two adjacent groups among R¹¹ to R¹⁸ are linked together to form the following hetero aromatic ring having the structure of Chemical Formula 3, 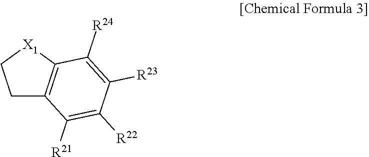
wherein, in the Chemical Formula 3,
X¹ is NR²⁵, O or S;
each of R²¹ to R²⁵ is independently a hydrogen atom, a halogen atom, an unsubstituted or substituted C₁-C₂₀ alkyl group, an unsubstituted or substituted C₁-C₂₀ alkyl silyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group; and
a dotted line indicates a fused portion, 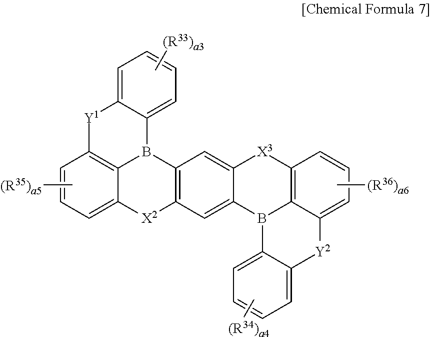
wherein, in the Chemical Formula 7,
Y¹ is O or NR³¹;
Y² is O or NR³²;
X² is O or NR³⁷;
X³ is O or NR³⁸;
each of R³¹ to R³⁸ is independently a hydrogen atom, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group, where each R³³ is identical to or different from each other when a3 is 2, 3 or 4, each R³⁴ is identical to or different from each other when a4 is 2, 3 or 4, each R³⁵ is identical to or different from each other when a5 is 2 or 3, and each R³⁶ is identical to or different from each other when a6 is 2 or 3, or
optionally,
R³¹ and R³³, R³¹ and R³⁵, R³⁵ and R³⁷, R³⁷ and R³⁴, R³⁴ and R³², R³² and R³⁶, R³⁶ and R³⁸ or R³⁸ and R³³ are linked together to form an unsubstituted or substituted hetero aromatic ring including a nitrogen atom or an oxygen atom;
each of a3 and a4 is independently 0, 1, 2, 3 or 4; and
each of a5 and a6 is independently 0, 1, 2 or 3, 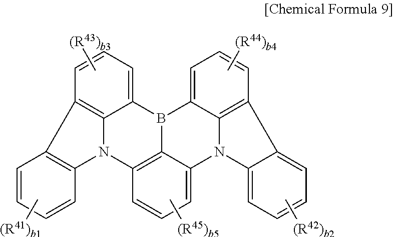
wherein, in the Chemical Formula 9,
each of R⁴¹ to R⁴⁴ is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group, where each R⁴¹ is identical to or different from each other when b1 is 2, 3 or 4, each R⁴² is identical to or different from each other when b2 is 2, 3 or 4, each R⁴³ is identical to or different from each other when b3 is 2 or 3, and each R⁴⁴ is identical to or different from each other when b4 is 2 or 3, or
optionally,
two adjacent R⁴¹ when b1 is 2, 3 or 4, two adjacent R⁴² when b2 is 2, 3 or 4, two adjacent R⁴³ when b3 is 2 or 3 or two adjacent R⁴⁴ when b4 is 2 or 3 are linked together to form an unsubstituted or substituted C₆-C₂₀ aromatic ring or an unsubstituted or substituted C₃-C₂₀ hetero aromatic ring;
R⁴⁵ is an unsubstituted or substituted C₆-C₃₀ aryl group, an unsubstituted or substituted C₃-C₃₀ hetero aryl group, an unsubstituted or substituted C₆-C₃₀ aryl amino group or an unsubstituted or substituted C₃-C₃₀ hetero aryl amino group, where each R⁴⁵ is identical to or different from each other when b5 is 2 or 3, or
optionally,
two adjacent R⁴⁵ when b5 is 2 or 3 are linked together to form an unsubstituted or substituted C₆-C₂₀ aromatic ring or an unsubstituted or substituted C₃-C₂₀ hetero aromatic ring;
each of b1 and b2 is independently 0, 1, 2, 3 or 4; and
each of b3, b4 and b5 is independently 0, 1, 2 or 3.

2. The organic light emitting diode of claim 1, wherein the first compound includes an organic compound having the following structure of Chemical Formula 4: 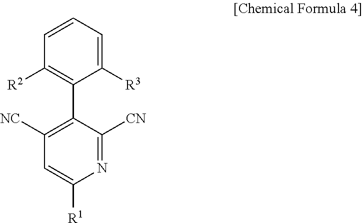
wherein, in the Chemical Formula 4,
each of R¹, R² and R³ is identical as defined in Chemical Formula 1.

3. The organic light emitting diode of claim 1, wherein the moiety having the structure of Chemical Formula 2 is any one of the following moieties:

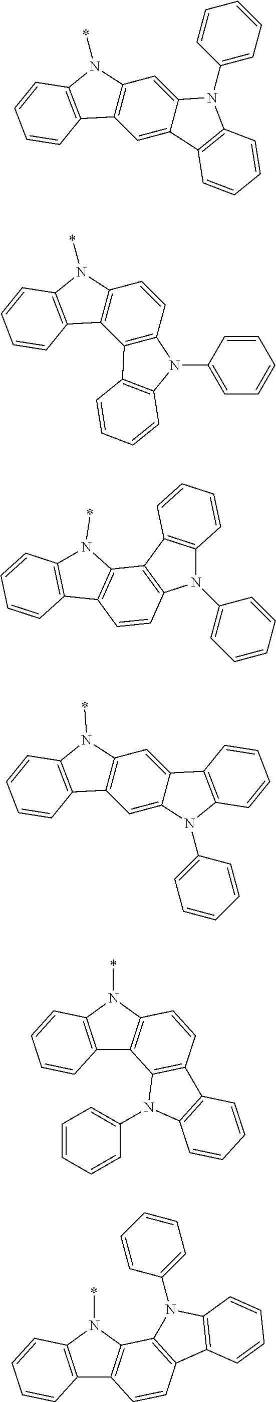 [SMILES: *n1c2ccccc2c2cc3c4ccccc4n(-c4ccccc4)c3cc21 ; *n1c2ccccc2c2c3c4ccccc4n(-c4ccccc4)c3ccc21 ; *n1c2ccccc2c2ccc3c(c4ccccc4n3-c3ccccc3)c21 ; *n1c2ccccc2c2cc3c(cc21)c1ccccc1n3-c1ccccc1 ; *n1c2ccccc2c2c1ccc1c3ccccc3n(-c3ccccc3)c12 ; *n1c2ccccc2c2ccc3c4ccccc4n(-c4ccccc4)c3c21]

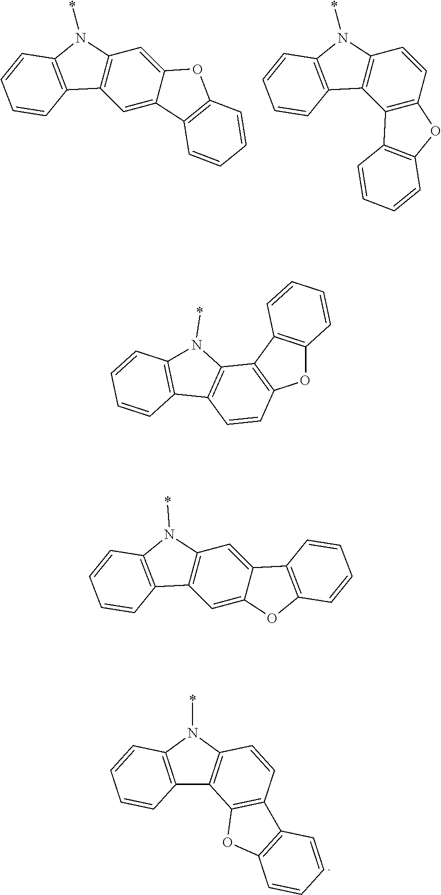

4. The organic light emitting diode of claim 1, wherein the first compound is at least one of the following organic compounds:

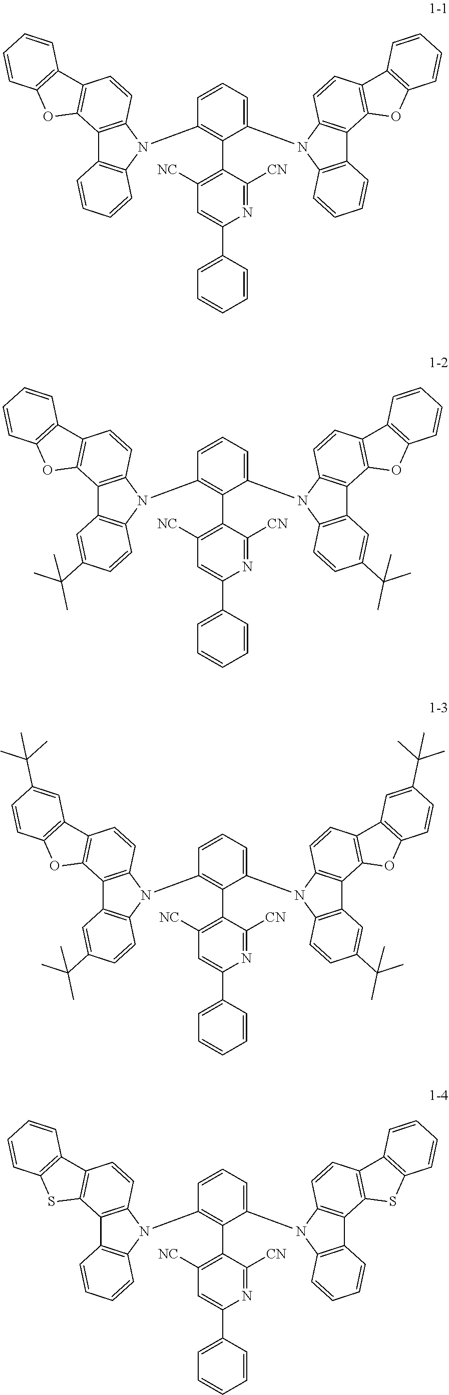 [SMILES: N#Cc1cc(-c2ccccc2)nc(C#N)c1-c1c(-n2c3ccccc3c3c4oc5ccccc5c4ccc32)cccc1-n1c2ccccc2c2c3oc4ccccc4c3ccc21 ; CC(C)(C)c1ccc2c(c1)c1c3oc4ccccc4c3ccc1n2-c1cccc(-n2c3ccc(C(C)(C)C)cc3c3c4oc5ccccc5c4ccc32)c1-c1c(C#N)cc(-c2ccccc2)nc1C#N ; CC(C)(C)c1ccc2oc3c(ccc4c3c3cc(C(C)(C)C)ccc3n4-c3cccc(-n4c5ccc(C(C)(C)C)cc5c5c6oc7ccc(C(C)(C)C)cc7c6ccc54)c3-c3c(C#N)cc(-c4ccccc4)nc3C#N)c2c1 ; N#Cc1cc(-c2ccccc2)nc(C#N)c1-c1c(-n2c3ccccc3c3c4sc5ccccc5c4ccc32)cccc1-n1c2ccccc2c2c3sc4ccccc4c3ccc21]

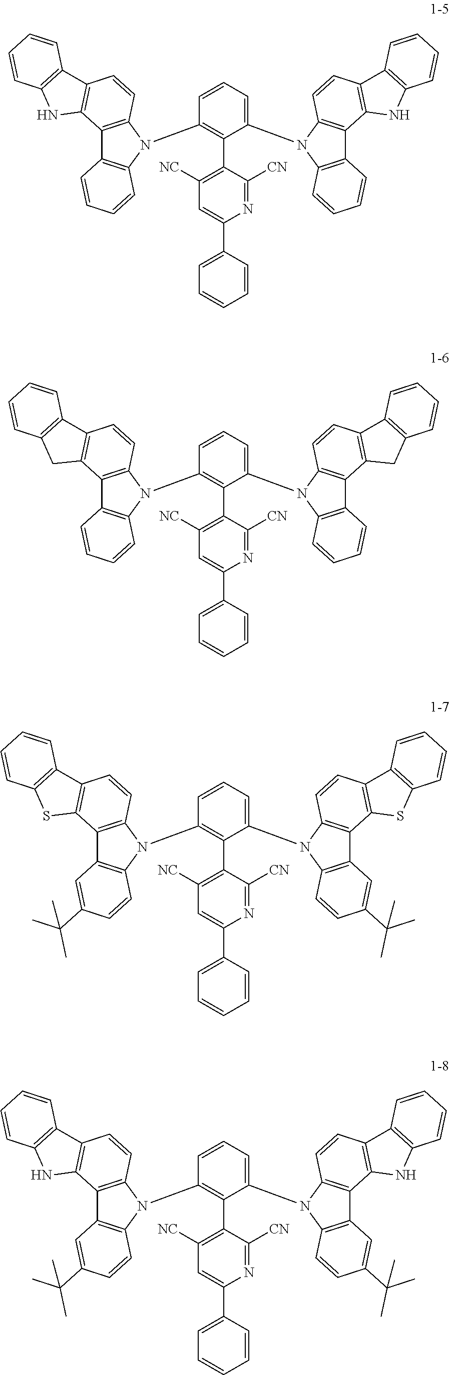 [SMILES: N#Cc1cc(-c2ccccc2)nc(C#N)c1-c1c(-n2c3ccccc3c3c4[nH]c5ccccc5c4ccc32)cccc1-n1c2ccccc2c2c3[nH]c4ccccc4c3ccc21 ; N#Cc1cc(-c2ccccc2)nc(C#N)c1-c1c(-n2c3ccccc3c3c4c(ccc32)-c2ccccc2C4)cccc1-n1c2ccccc2c2c3c(ccc21)-c1ccccc1C3 ; CC(C)(C)c1ccc2c(c1)c1c3sc4ccccc4c3ccc1n2-c1cccc(-n2c3ccc(C(C)(C)C)cc3c3c4sc5ccccc5c4ccc32)c1-c1c(C#N)cc(-c2ccccc2)nc1C#N ; CC(C)(C)c1ccc2c(c1)c1c3[nH]c4ccccc4c3ccc1n2-c1cccc(-n2c3ccc(C(C)(C)C)cc3c3c4[nH]c5ccccc5c4ccc32)c1-c1c(C#N)cc(-c2ccccc2)nc1C#N]

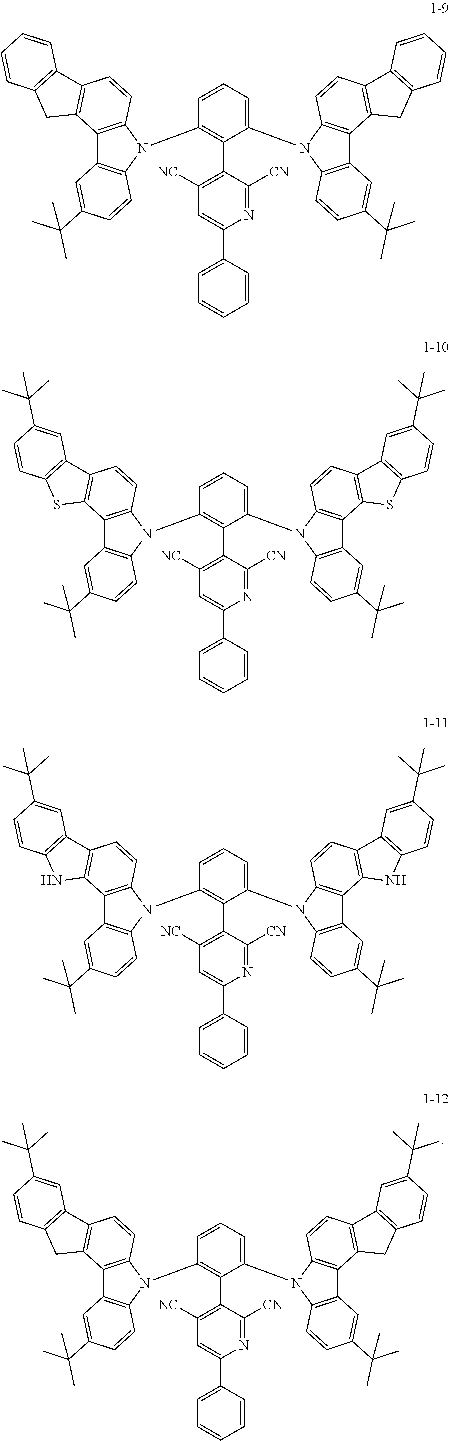

5. The organic light emitting diode of claim 1, wherein the second compound having the structure of Chemical Formula 7 is at least one of the following organic compounds:

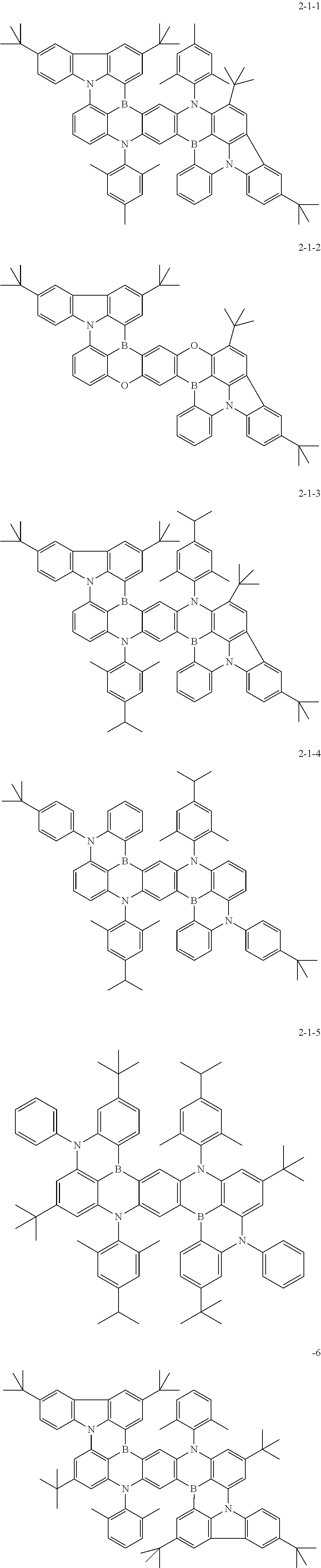

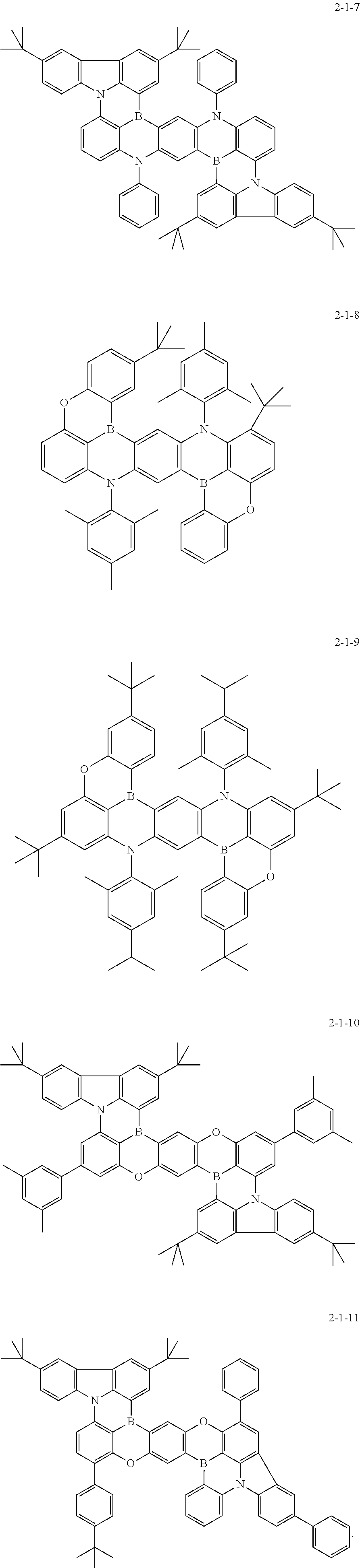

6. The organic light emitting diode of claim 1, wherein the second compound having the structure of Chemical Formula 9 is at least one of the following organic compounds:

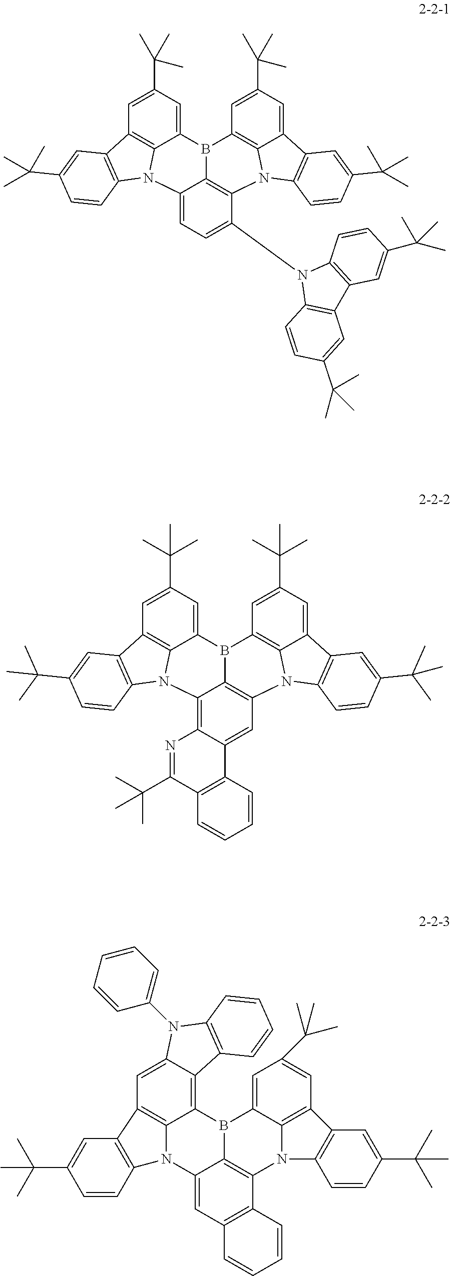

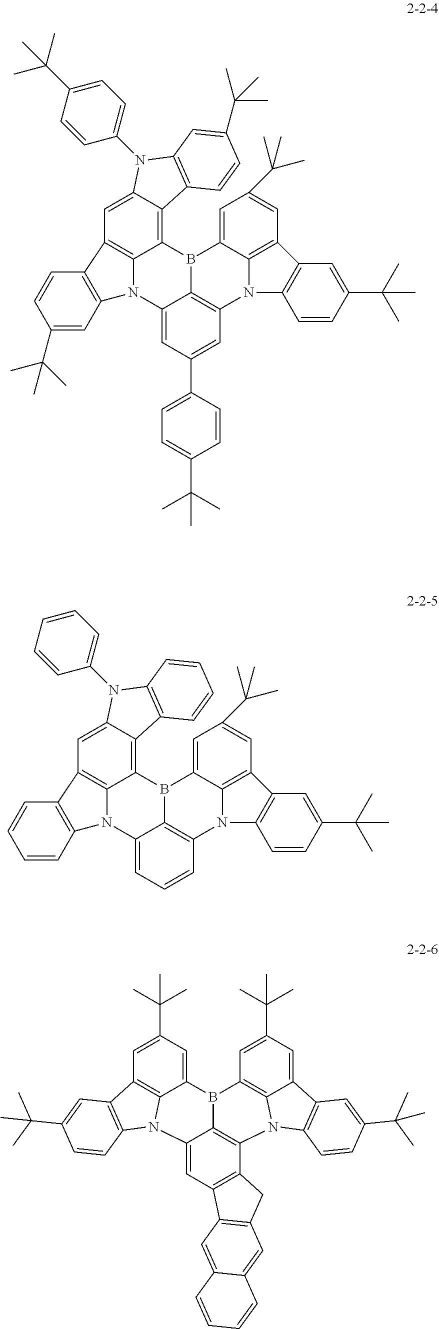

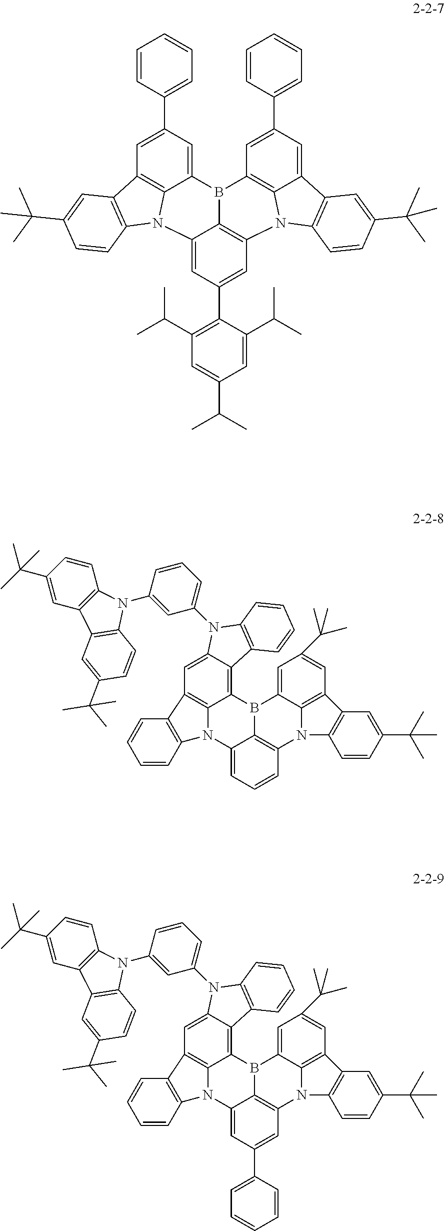

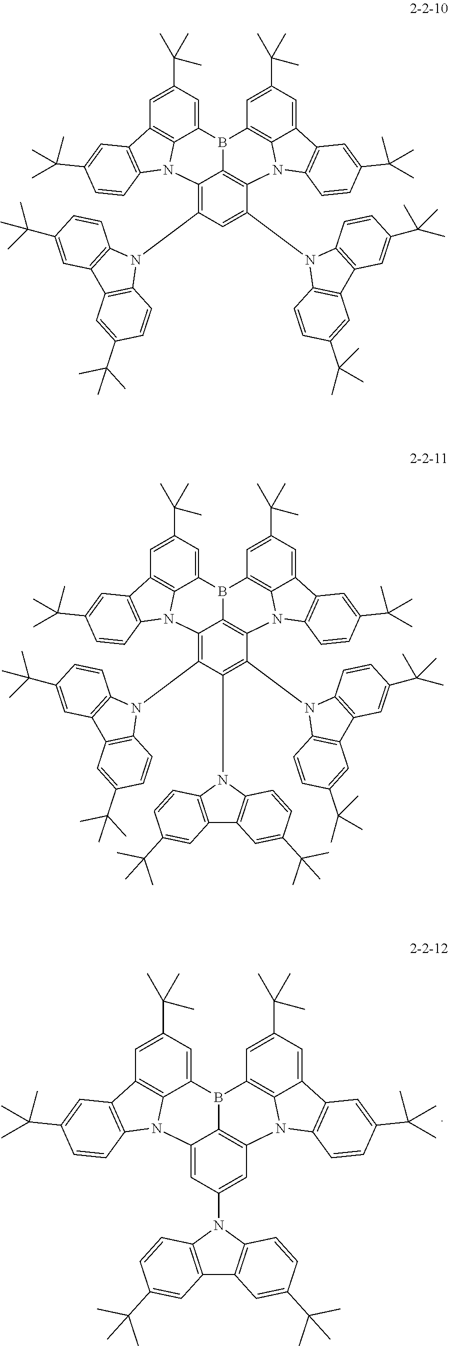

7. The organic light emitting diode of claim 1, wherein the at least one emitting material layer is a single-layered emitting material layer.

8. The organic light emitting diode of claim 7, wherein the single-layered emitting material layer further includes a third compound.

9. The organic light emitting diode of claim 8, wherein the third compound includes an organic compound having the following structure of Chemical Formula 11: 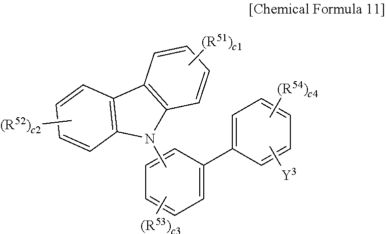
wherein, in the Chemical Formula 11,
each of R⁵¹ and R⁵² is independently an unsubstituted or substituted C₁-C₂₀ alkyl group, an unsubstituted or substituted C₆-C₃₀ aryl group or an unsubstituted or substituted C₃-C₃₀ hetero aryl group, where each R⁵¹ is identical to or different from each other when c1 is 2, 3 or 4, and where each R⁵² is identical to or different from each other when c2 is 2, 3 or 4;
each of R⁵³ and R⁵⁴ is independently an unsubstituted or substituted C₁-C₂₀ alkyl group, an unsubstituted or substituted C₆-C₃₀ aryl group or an unsubstituted or substituted C₃-C₃₀ hetero aryl group, or
optionally, R⁵³ and R⁵⁴ are linked together to form an unsubstituted or substituted hetero ring, where each R⁵³ is identical to or different from each other when c3 is 2, 3 or 4, and where each R⁵⁴ is identical to or different from each other when c4 is 2, 3 or 4;
Y³ has the following structure of Chemical Formula 12 or Chemical Formula 13;
each of c1, c2, c3 and c4 is independently 0, 1, 2, 3 or 4, 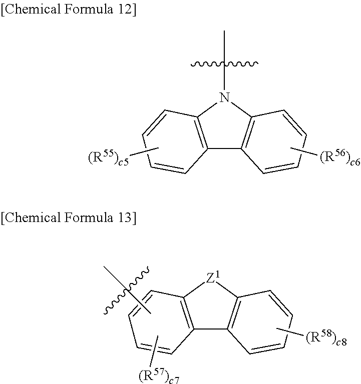
wherein, in the Chemical Formulae 12 and 13,
each of R⁵⁵, R⁵⁶, R⁵⁷ and R⁵⁸ is independently an unsubstituted or substituted C₁-C₂₀ alkyl group, an unsubstituted or substituted C₆-C₃₀ aryl group or an unsubstituted or substituted C₃-C₃₀ hetero aryl group, where each R⁵⁵ is identical to or different from each other when c5 is 2, 3 or 4, each R⁵⁶ is identical to or different from each other when c6 is 2, 3 or 4, each R⁵⁷ is identical to or different from each other when c7 is 2 or 3, and each R⁵⁸ is identical to or different from each other when c8 is 2, 3 or 4;
each of c5, c6 and c8 is independently 0, 1, 2, 3 or 4;
c7 is 0, 1, 2 or 3; and
Z¹ is NR⁵⁹, O or S, where R⁵⁹ is a hydrogen atom an unsubstituted or substituted C₁-C₂₀ alkyl group, an unsubstituted or substituted C₆-C₃₀ aryl group or an unsubstituted or substituted C₃-C₃₀ hetero aryl group.

10. The organic light emitting diode of claim 1, wherein the at least one emitting material layer includes:
a first emitting material layer; and
a second emitting material layer disposed between the first electrode and the first emitting material layer or disposed between the first emitting material layer and the second electrode, and
wherein the first emitting material layer includes the first compound and the second emitting material layer includes the second compound.

11. The organic light emitting diode of claim 10, wherein the first emitting material layer further includes a third compound and the second emitting material layer further includes a fourth compound.

12. The organic light emitting diode of claim 11, wherein each of the third compound and the fourth compound independently includes an organic compound having the following structure of Chemical Formula 11: 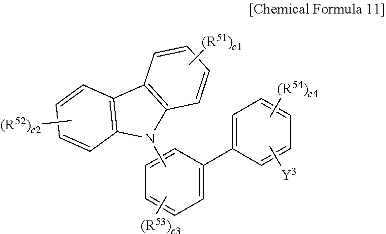
wherein, in the Chemical Formula 11,
each of R⁵¹ and R⁵² is independently an unsubstituted or substituted C₁-C₂₀ alkyl group, an unsubstituted or substituted C₆-C₃₀ aryl group or an unsubstituted or substituted C₃-C₃₀ hetero aryl group, where each R⁵¹ is identical to or different from each other when c1 is 2, 3 or 4, and where each R⁵² is identical to or different from each other when c2 is 2, 3 or 4;
each of R⁵³ and R⁵⁴ is independently an unsubstituted or substituted C₁-C₂₀ alkyl group, an unsubstituted or substituted C₆-C₃₀ aryl group or an unsubstituted or substituted C₃-C₃₀ hetero aryl group, or
optionally, R⁵³ and R⁵⁴ are linked together to form an unsubstituted or substituted hetero ring, where each R⁵³ is identical to or different from each other when c3 is 2, 3 or 4, and where each R⁵⁴ is identical to or different from each other when c4 is 2, 3 or 4;
Y³ has the following structure of Chemical Formula 12 or Chemical Formula 13;
each of c1, c2, c3 and c4 is independently 0, 1, 2, 3 or 4, 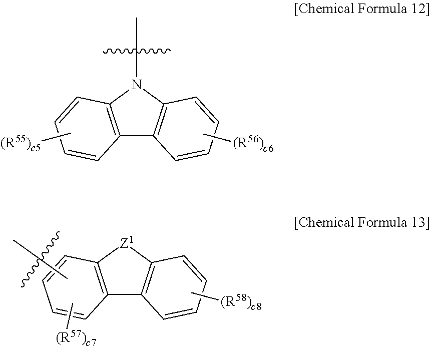
wherein, in the Chemical Formulae 12 and 13,
each of R⁵⁵, R⁵⁶, R⁵⁷ and R⁵⁸ is independently an unsubstituted or substituted C₁-C₂₀ alkyl group, an unsubstituted or substituted C₆-C₃₀ aryl group or an unsubstituted or substituted C₃-C₃₀ hetero aryl group, where each R⁵⁵ is identical to or different from each other when c5 is 2, 3 or 4, each R⁵⁶ is identical to or different from each other when c6 is 2, 3 or 4, each R⁵⁷ is identical to or different from each other when c7 is 2 or 3, and each R⁵⁸ is identical to or different from each other when c8 is 2, 3 or 4;
each of c5, c6 and c8 is independently 0, 1, 2, 3 or 4;
c7 is 0, 1, 2 or 3; and
Z¹ is NR⁵⁹, O or S, where R⁵⁹ is a hydrogen atom an unsubstituted or substituted C₁-C₂₀ alkyl group, an unsubstituted or substituted C₆-C₃₀ aryl group or an unsubstituted or substituted C₃-C₃₀ hetero aryl group.

13. The organic light emitting diode of claim 10, wherein the at least one emitting material layer further includes a third emitting material layer disposed oppositely to the second emitting material layer with respect to the first emitting material layer.

14. The organic light emitting diode of claim 13, wherein the third emitting material layer includes a fifth compound and a sixth compound, and wherein the fifth compound includes the organic compound having the structure of Chemical Formula 7 or Chemical Formula 9.

15. The organic light emitting diode of claim 14, wherein the sixth compound includes an organic compound having the following structure of Chemical Formula 11: 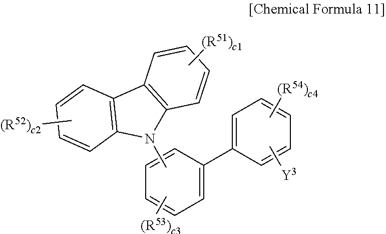
wherein, in the Chemical Formula 11,
each of R⁵¹ and R⁵² is independently an unsubstituted or substituted C₁-C₂₀ alkyl group, an unsubstituted or substituted C₆-C₃₀ aryl group or an unsubstituted or substituted C₃-C₃₀ hetero aryl group, where each R⁵¹ is identical to or different from each other when c1 is 2, 3 or 4, and where each R⁵² is identical to or different from each other when c2 is 2, 3 or 4;
each of R⁵³ and R⁵⁴ is independently an unsubstituted or substituted C₁-C₂₀ alkyl group, an unsubstituted or substituted C₆-C₃₀ aryl group or an unsubstituted or substituted C₃-C₃₀ hetero aryl group, or
optionally, R⁵³ and R⁵⁴ are linked together to form an unsubstituted or substituted hetero ring, where each R⁵³ is identical to or different from each other when c3 is 2, 3 or 4, and where each R⁵⁴ is identical to or different from each other when c4 is 2, 3 or 4;
Y³ has the following structure of Chemical Formula 12 or Chemical Formula 13;
each of c1 c2, c3 and c4 is independently 0, 1, 2, 3 or 4, 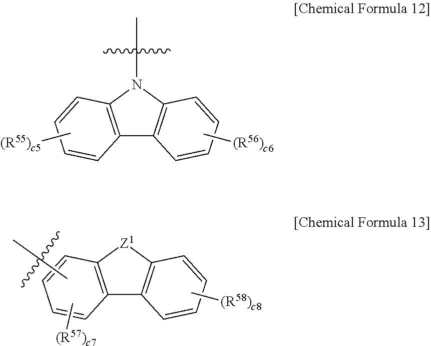
wherein, in the Chemical Formulae 12 and 13,
each of R⁵⁵, R⁵⁶, R⁵⁷ and R⁵⁸ is independently an unsubstituted or substituted C₁-C₂₀ alkyl group, an unsubstituted or substituted C₆-C₃₀ aryl group or an unsubstituted or substituted C₃-C₃₀ hetero aryl group, where each R⁵⁵ is identical to or different from each other when c5 is 2, 3 or 4, each R⁵⁶ is identical to or different from each other when c6 is 2, 3 or 4, each R⁵⁷ is identical to or different from each other when c7 is 2 or 3, and each R⁵⁸ is identical to or different from each other when c8 is 2, 3 or 4;
each of c5, c6 and c8 is independently 0, 1, 2, 3 or 4;
c7 is 0, 1, 2 or 3; and
Z¹ is NR⁵⁹, O or S, where R⁵⁹ is a hydrogen atom an unsubstituted or substituted C₁-C₂₀ alkyl group, an unsubstituted or substituted C₆-C₃₀ aryl group or an unsubstituted or substituted C₃-C₃₀ hetero aryl group.

16. The organic light emitting diode of claim 1, wherein the emissive layer includes:
a first emitting part disposed between the first electrode and the second electrode;
a second emitting part disposed between the first emitting part and the second electrode; and
a first charge generation layer disposed between the first emitting part and the second emitting part, and
wherein at least one of the first emitting part and the second emitting part includes the at least one emitting material layer.

17. The organic light emitting diode of claim 16, wherein the second emitting part includes the at least one emitting material layer and the first emitting part includes a blue emitting material layer.

18. The organic light emitting diode of claim 17, wherein the second emitting part includes:
a first layer disposed between the first charge generation layer and the second electrode; and
a second layer disposed between the first layer and the second electrode, and
wherein the one of the first layer and the second layer includes the at least one emitting material layer.

19. The organic light emitting diode of claim 18, wherein the second layer includes the at least one emitting material layer and the first layer includes a red emitting material layer.

20. The organic light emitting diode of claim 19, wherein the second emitting part further includes a third layer disposed between the first layer and the second layer, and wherein the third layer includes a yellow-green emitting material layer.

21. The organic light emitting diode of claim 16, wherein the emissive layer further includes:
a third emitting part disposed between the second emitting part and the second electrode; and
a second charge generation layer disposed between the second emitting part and the third emitting part, and
wherein at least one of the first emitting part, the second emitting part, and the third emitting part includes the at least one emitting material layer.

22. An organic light emitting device, including:
a substrate; and
the organic light emitting diode of claim 1 on the substrate.
